(19) United States
(12) Patent Application Publication
(10) Pub. No.: US 2026/0133658 A1
(43) Pub. Date: May 14, 2026

(54) DISPLAY APPARATUS

(71) Applicant: LG Display Co., Ltd., Seoul (KR)

(72) Inventors: HoonBae Kim, Paju-si (KR); NamYong Gong, Paju-si (KR); SungChul Kim, Paju-si (KR); SunYeop Kim, Paju-si (KR); Sung-Jin Kang, Paju-si (KR); Jongsung Kim, Paju-si (KR)

(73) Assignee: LG Display Co., Ltd., Seoul (KR)

(21) Appl. No.: 19/333,032

(22) Filed: Sep. 18, 2025

(30) Foreign Application Priority Data
Nov. 11, 2024 (KR) 10-2024-0159058

(51) Int. Cl. G06F 3/041; G06F 3/044; H01L 25/16; H10H 29/49

(52) U.S. Cl. CPC G06F 3/04186; G06F 3/0446; H10H 29/49; H10W 90/00

(57) ABSTRACT

A display apparatus can include a substrate having a display area and a non-display area, pixel driving circuits provided in the display area, first electrodes connected to the pixel driving circuit, light emitting devices electrically connected to the first electrodes, and second electrodes connected to the light emitting devices. An image signal line is connected to a pixel driving circuit among the pixel driving circuits, and the pixel driving circuit is configured to selectively connect the image signal line to the first electrodes or the second electrodes.

### CROSS-REFERENCE TO RELATED APPLICATIONS

This application claims priority to Korean Patent Application No. 10-2024-0159058, filed in the Republic of Korea on Nov. 11, 2024, which is hereby expressly incorporated by reference in its entirety.

### BACKGROUND

### Field of Technology

The present disclosure relates to a display apparatus.

### Discussion of the Related Art

A display apparatus is applied to various electronic devices such as TVs, mobile phones, laptops, and tablets.

Display apparatuses include an organic light emitting display (OLED) that emits light by itself and a liquid crystal display (LCD) that requires a separate light source.

Recently, a display apparatus including a light emitting diode (LED) has attracted attention as a next-generation display apparatus. The light emitting diode is made of an inorganic material, not an organic material. Accordingly, compared to the liquid crystal display or the organic light emitting display, a display apparatus including the light emitting diode has a faster lighting speed, has excellent luminous efficiency, and can display an image having high luminance.

### SUMMARY OF THE DISCLOSURE

Accordingly, the present disclosure is directed to providing a display apparatus that substantially obviates one or more problems due to limitations and disadvantages of the related art.

An aspect of the present disclosure is directed to providing a display apparatus capable of changing a size of a touch electrode corresponding to a touch coordinate, depending on the type of touch to be sensed.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other advantages and in accordance with the purpose of the disclosure, as embodied and broadly described herein, there is provided a display apparatus comprising a substrate including a display area and a non-display area, pixel driving circuits disposed in the display area, first electrodes connected to the pixel driving circuits, light emitting devices disposed on the first electrodes, and second electrodes disposed on the light emitting devices, wherein an image signal line is connected to a pixel driving circuit, and wherein the pixel driving circuit is configured to selectively connect the image signal line to the first electrodes or the second electrodes.

It is to be understood that both the foregoing general description and the following detailed description of the present disclosure are example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view illustrating a display apparatus according to an embodiment of the present disclosure;

FIG. 2 is a plan view of a display apparatus according to an embodiment of the present disclosure;

FIG. 3 is an enlarged example diagram of a portion of a display apparatus according to an embodiment of the present disclosure;

FIG. 4 is an example diagram illustrating a structure of a pixel driving circuit applied to a display apparatus according to an embodiment of the present disclosure;

FIGS. 5 to 7B are plan views of a display panel applied to a display apparatus according to an embodiment of the present disclosure;

FIG. 8 is an example diagram illustrating a cross-sectional surface of a display panel applied to a display apparatus according to an embodiment of the present disclosure;

FIG. 9 is a cross-sectional view of a light emitting device applied to a display apparatus according to an embodiment of the present disclosure;

FIG. 10A is an example diagram illustrating a structure of a touch electrode part and a display driver applied to a display apparatus according to an embodiment of the present disclosure;

FIG. 10B is an example diagram illustrating a structure of the display driver illustrated in FIG. 10A in detail;

FIG. 11A is an example diagram illustrating structures of a sub-touch electrode and a pixel driving circuit applied to a display apparatus according to an embodiment of the present disclosure;

FIG. 11B is an example diagram illustrating a connection structure of a sub-touch electrode and a pixel driving circuit applied to a display apparatus according to an embodiment of the present disclosure;

FIG. 11C is an example diagram illustrating a connection relationship between a pixel driving circuit and light emitting devices applied to a display apparatus according to an embodiment of the present disclosure;

FIG. 11D is an example diagram illustrating a light emitting signal applied to a display apparatus according to an embodiment of the present disclosure;

FIG. 11E is an example diagram illustrating a pixel circuit applied to a display apparatus according to an embodiment of the present disclosure;

FIG. 11F is an example diagram illustrating a touch sensing method in a display apparatus according to an embodiment of the present disclosure;

FIG. 11G is an example diagram illustrating a display period and a touch sensing period applied to a display apparatus according to an embodiment of the present disclosure; and

FIGS. 12 to 15 are diagrams illustrating electronic devices to which a display apparatus according to embodiments of the present disclosure is applied.

### DETAILED DESCRIPTION OF THE EMBODIMENTS

Reference will now be made in detail to the example embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When the terms such as “comprise,” “have,” and “include” described in the present disclosure are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms such as “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

In describing elements of the present disclosure, the terms such as “first,” “second,” “A,” “B,” “(a),” “(b),” etc. can be used. These terms are intended to identify the corresponding elements from the other elements, and basis, order, or number of the corresponding elements should not be limited by these terms. The expression that an element or layer is “connected,” “coupled,” or “adhered” to another element or layer should be understood the element or layer cannot only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the all combinations of items proposed from two or more of the first item, the second item, and the third item as well as the first item, the second item, or the third item. Further, the term “can” used herein includes all meanings and definitions of the word “may”.

Features of various embodiments of the present disclosure can be partially or overall coupled to or combined with each other, and can be variously inter-operated with each other and driven technically as those skilled in the art can sufficiently understand.

The embodiments of the present disclosure can be carried out independently from each other, or can be carried out together in co-dependent relationship. All the components of each display apparatus/device according to all embodiments of the present disclosure are operatively coupled and configured.

Hereinafter, embodiments of the present disclosure will be described in detail with reference to the accompanying drawings.

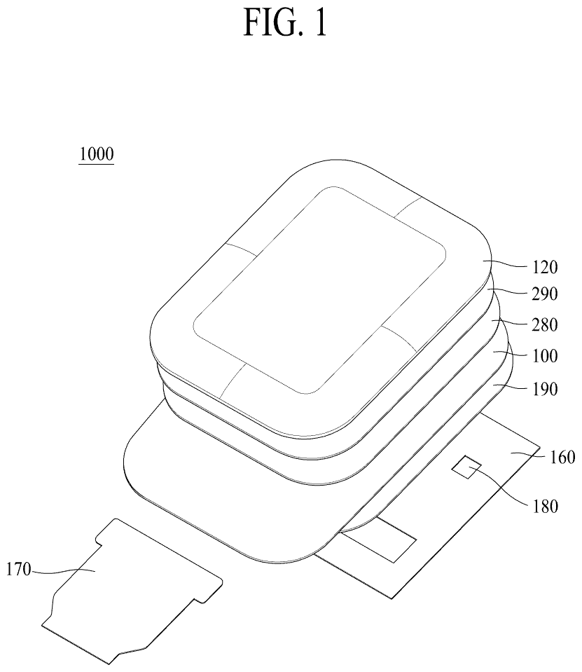

FIG. 1 is a perspective view illustrating a display apparatus according to an embodiment of the present disclosure.

Referring to FIG. 1, a display apparatus 1000 according to an embodiment of the present disclosure can include a display panel 100, a polarizing layer 280, an adhesive layer 290, a cover member 120, a support substrate 190, a flexible circuit board 170, and a printed circuit board 160.

The display panel 100 can display information and an image to be provided to a user.

The polarizing layer 280 can be disposed on the display panel 100. The polarizing layer 280 can prevent or reduce light generated from an external light source from entering the display panel 100 to affect a light emitting device or the like.

The adhesive layer 290 can attach the cover member 120 to the display panel 100. The adhesive layer 290 can be disposed between the polarizing layer 280 and the cover member 120 to attach the cover member 120 to the polarizing layer 280. The adhesive layer 290 can include one of an optically clear adhesive (OCA), an optically clear resin (OCR), and a pressure sensitive adhesive (PSA).

The cover member 120 can be disposed on the polarizing layer 280. The cover member 120 can be disposed on the adhesive layer 290. The cover member 120 can be a member for protecting the display panel 100. The cover member 120 can be formed of a transparent material.

The support substrate 190 can be disposed between the display panel 100 and the printed circuit board 160. The support substrate 190 can reinforce rigidity of the display panel 100. The support substrate 190 can be a back plate.

The flexible circuit board 170 and the printed circuit board 160 can be disposed on a bottom of the display panel 100. The flexible circuit board 170 and the printed circuit board 160 can be disposed on one edge of the display panel 100. One side of the flexible circuit board 170 can be attached to the display panel 100 and the other side of the flexible circuit board 170 can be attached to the printed circuit board 160. The flexible circuit board 170 can be a flexible film, but embodiments of the present disclosure are not limited thereto.

The printed circuit board 160 can include at least one hole 180. An internal component that senses ambient light or temperature can be disposed in an area corresponding to at least one hole 180. For example, the internal component can include at least one of an ambient light sensor (ALS) and a temperature sensor.

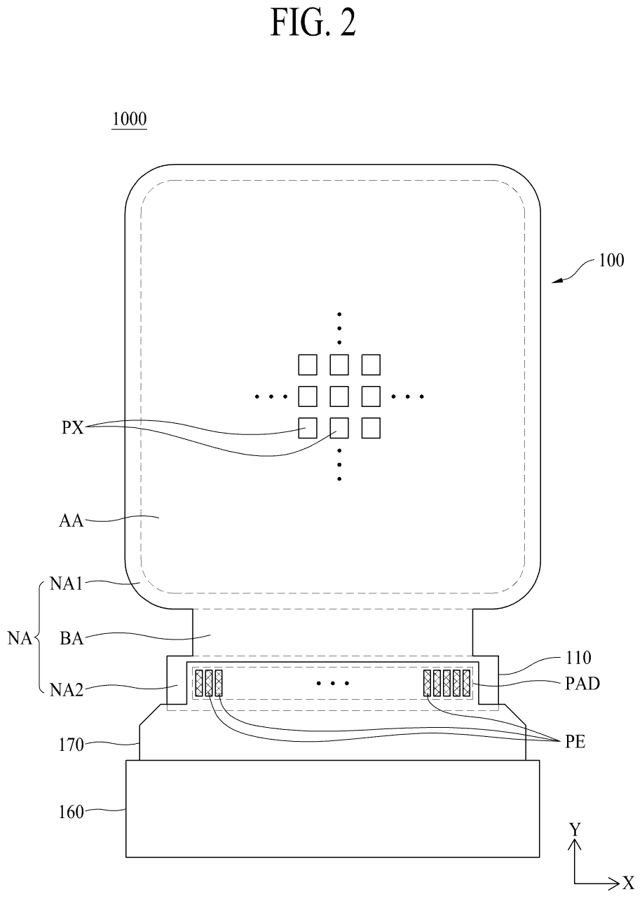

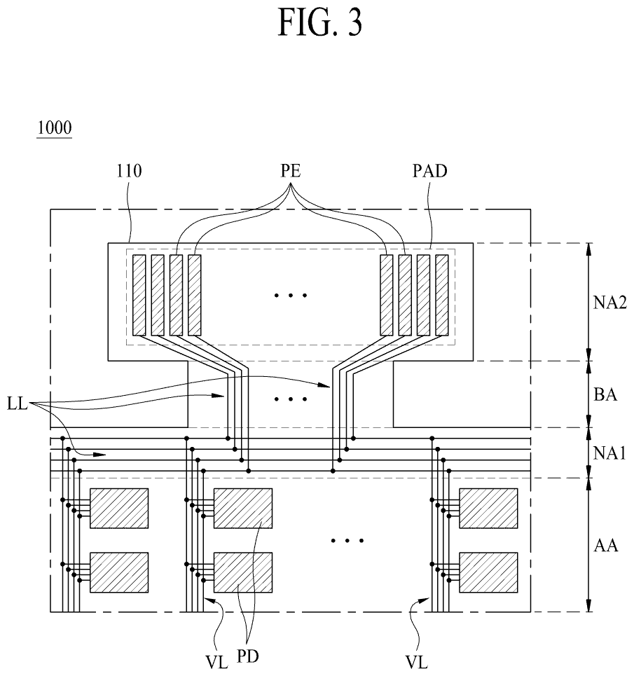

FIG. 2 is a plan view of a display apparatus according to an embodiment of the present disclosure and FIG. 3 is an enlarged example diagram of a portion of a display apparatus according to an embodiment of the present disclosure.

Referring to FIGS. 2 and 3, the display apparatus 1000 can include the display panel 100, the flexible circuit board 170, and the printed circuit board 160.

The display panel 100 can include a substrate 110. The substrate 110 can be a member that supports other components of the display apparatus 1000. The substrate 110 can be made of an insulating material. For example, the substrate 110 can be made of glass or resin. Further, the substrate 110 can be made of a material having flexibility. For example, the substrate 110 can be made of a plastic material having flexibility, such as polyimide (PI).

For example, the display panel 100 can include a display area AA (or active area) and a non-display area NA (or non-active area). Therefore, the substrate 110 can include the display area AA and the non-display area NA. The display area AA and the non-display area NA can be applied not only to the description of the substrate 110, but also to the description of the display apparatus 1000.

The display area AA can be an area in which an image is displayed. The display area AA can include a plurality of pixels PX. Each of the plurality of pixels PX can include a plurality of sub-pixels. At least one sub-pixel can be disposed in each of the plurality of sub-pixels.

A type of the light emitting device can be variously changed based on a type of the display apparatus 1000. For example, when the display apparatus 1000 is an inorganic light emitting display apparatus, the light emitting device can be a light-emitting diode (LED), a micro light-emitting diode (Micro-LED), or a mini-light-emitting diode (MLED).

The display area AA can be configured in various shapes according to a design of the display apparatus 1000. For example, the display area AA can be configured in a rectangular shape having four rounded corners. For another example, the display area AA can be configured in a rectangular having four corners, each of which has a right-angle shape, or a circular shape.

Referring to FIG. 3, a plurality of pixel driving circuits PD can be disposed in the display area AA. The plurality of pixel driving circuits PD can be circuits for driving light emitting devices provided in the plurality of sub-pixels.

Each of the plurality of pixel driving circuits PD can include a storage capacitor and a plurality of transistors including a driving transistor. In addition, each of the plurality of pixel driving circuits PD can control a light emitting operation of the plurality of light emitting devices by supplying a control signal, a power source, and a driving current to the light emitting devices provided in the plurality of sub-pixels. For example, the pixel driving circuit PD can include a power line and a signal line for controlling light emission on/off and/or light emission time of the light emitting device. For example, the plurality of pixel driving circuits PD can be manufactured using a metal-oxide-silicon field effect transistor (MOSFET) manufacturing process on a semiconductor substrate.

The non-display area NA can be an area in which no image is displayed. Various lines, circuits, and the like for driving the plurality of pixels PX of the display area AA can be disposed in the non-display area NA. For example, various lines and driving circuits can be mounted in the non-display area NA. Further, a pad part PAD to which an integrated circuit, a printed circuit, and the like is connected can be disposed in the non-display area NA.

For example, the driving circuit can be a data driving circuit and/or a gate driving circuit. Lines to which a control signal for controlling the driving circuits is supplied can be disposed in the non-display area NA. For example, the control signal can include a clock signal, an input data enable signal, and synchronization signals. The control signal can be received through the pad part PAD. For example, link lines LL for transmitting a signal can be disposed in the non-display area NA. For example, a driving component such as the flexible circuit board 170 and the printed circuit board 160 can be connected to the pad part PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA can be an area extending from at least one of a plurality of sides of the first non-display area NA1 and can be a bendable area. The second non-display area NA2 is an area extending from the bending area BA, and the pad part PAD can be disposed in the second non-display area NA2. For example, the bending area BA can be bent, and a remaining area of the substrate 110 except for the bending area BA can be flat. In this case, as the bending area BA is bent, the second non-display area NA2 can be disposed on a rear surface of the display area AA.

A plurality of link lines LL can be disposed in the non-display area NA. The plurality of link lines LL can be lines for transmitting various signals from one or more flexible circuit boards (or flexible films) 170 and the printed circuit board 160 to the display area AA. The plurality of link lines LL can extend from a plurality of pad electrodes PE of the second non-display area NA2 toward the bending area BA and the first non-display area NA1 to be electrically connected to a plurality of driving lines VL of the display area AA.

The plurality of pixel driving circuits PD can be driven by signals transmitted from one or more flexible circuit boards (or flexible films) 170 and the printed circuit board 160 through the driving line VL in the display area AA and the link line LL in the non-display area NA.

For example, each of the driving line VL and the link line LL can be a line for transmitting a signal output from the flexible circuit board (or flexible film) 170 and the printed circuit board 160 to the pixel driving circuit PD. The driving line VL can be disposed in the display area AA to be electrically connected to the pixel driving circuit PD. The driving line VL can extend from the display area AA toward the non-display area NA to be electrically connected to the link line LL. Accordingly, the signal output from the flexible circuit board (or flexible film) 170 and the printed circuit board 160 can be transmitted to the pixel driving circuit PD through the link line LL and the driving line VL.

As the bending area BA is bent, a portion of the link line LL can also be bent with the bending area BA. Stress is concentrated on a portion of the bent link line LL, and thus, a crack can occur in the link line LL. The link line LL can be formed of a conductive material having excellent ductility in order to reduce cracks when the bending area BA is bent. For example, the link line LL can be formed of a conductive material having excellent ductility, such as gold (Au), silver (Ag), aluminum (Al), etc. Further, the link line LL can be formed of one of various conductive materials used in the display area AA. For example, the link line LL can be formed of molybdenum (Mo), chromium (Cr), titanium (Ti), nickel (Ni), neodymium (Nd), copper (Cu), an alloy of silver (Ag) and magnesium (Mg), or an alloy thereof. The link line LL can be formed in a multilayer structure including various conductive materials. For example, the link line LL can be formed in a triple layer structure of titanium (Ti)/aluminum (Al)/titanium (Ti).

The link line LL can be configured in various shapes to reduce stress. At least a portion of the link line LL disposed on the bending area BA can extend in a same direction as the extending direction of the bending area BA, or can extend in a direction different from the extending direction of the bending area BA to reduce stress. For example, when the bending area BA extends in one direction from the first non-display area NA1 to the second non-display area NA2, at least a portion of the link line LL disposed on the bending area BA can extend in a direction inclined to the one direction.

For another example, at least a portion of the link line LL can be formed in various shapes of patterns. For example, at least a portion of the link line LL disposed on the bending area BA can have a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged.

Therefore, in order to minimize the stress concentrated on the link line LL and the crack due to the stress, the shape of the link line LL can be formed in various shapes including the above-described shape.

According to the present disclosure, a width of the second non-display area NA2 in which the plurality of pad electrodes PE is disposed can be wider than a width of the bending area BA in which only the plurality of link lines LL is disposed. Further, a width of the display area AA in which the plurality of sub-pixels is disposed can be wider than the width of the bending area BA in which only the plurality of link line LL is disposed. A substrate 110 in which a width of the bending area BA is narrower than a width of other areas of the substrate 110 is illustrated in FIGS. 2 and 3. However, a shape of the substrate 110 including the bending area BA is example, and thus, embodiments of the present disclosure are not limited thereto.

A pad part PAD including the plurality of pad electrodes PE can be disposed in the second non-display area NA2. A driving component including one or more the flexible circuit boards (or flexible films) 170 and the printed circuit board 160 can be attached to or bonded to the pad part PAD. The plurality of pad electrodes PE are electrically connected to one or more flexible circuit boards (or flexible films), and can transmit various signals (or power) received from the printed circuit board 160 and the flexible circuit board (or flexible film) 170 to the plurality of pixel driving circuits PD in the display area AA.

The flexible circuit board (or flexible film) 170 can be a film having a flexibility and various components can be disposed on the flexible circuit board. For example, a driving IC such as a gate driver IC or a data driver IC can be disposed on the flexible circuit board (or flexible film). In the following description, the driving IC can be referred to as a driving driver.

The driving IC can be a component that processes data and a driving signal for displaying an image. The driving IC can be disposed by a method such as a chip on glass (COG), a chip on film (COF), a tape carrier package (TCP), or the like, but embodiments of the present disclosure are not limited thereto. The flexible circuit board (or flexible film) 170 can be attached to or bonded on a plurality of pad electrodes PE through a conductive adhesive layer.

The printed circuit board 160 can be electrically connected to one or more flexible circuit boards (or flexible films) 170, and supply signals to the driving IC. The printed circuit board 160 can be disposed on one side of the flexible circuit board (or flexible film) 170 to be electrically connected to the flexible circuit board (or flexible film). Various components for supplying various signals to the driving IC can be disposed on the printed circuit board 160. For example, various components, such as a timing controller, a power supply part, a memory, a processor, etc., can be disposed on the printed circuit board 160. For example, the printed circuit board 160 can include a power management integrated circuit (PMIC).

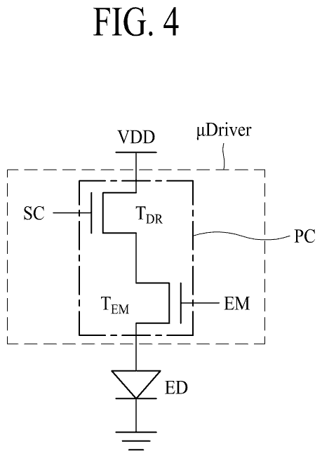

FIG. 4 is an example diagram illustrating a structure of a pixel driving circuit applied to a display apparatus according to an embodiment of the present disclosure.

The pixel driving circuit PD described with reference to FIG. 3 can be a micro-driver (μDriver) illustrated in FIG. 4. FIG. 4 illustrates that one light emitting device ED is connected to one micro-driver (μDriver), but is not limited thereto.

For example, eight light emitting devices ED can be connected to one micro-driver (μDriver). For another example, 16 light emitting devices ED can be connected to one micro-driver (μDriver) and 32 light emitting devices ED or 64 light emitting devices ED can be connected to one micro-driver (μDriver). The light emitting device ED can be a micro light emitting device (μLED). In addition, one pixel driving circuit PD (e.g., micro-driver (μDriver)) can be connected to at least two light emitting devices ED. In this case, one pixel driving circuit PD (e.g., micro-driver (μDriver)) can include one or more pixel circuits PC illustrated in FIG. 4. The pixel circuit PC can be connected to at least one light emitting device ED. The pixel circuit PC included in the micro driver μDriver can include a driving transistor T_{DR} and a light emitting transistor T_{EM}.

For example, a high potential power supply voltage VDD can be applied to a first electrode of the driving transistor T_{DR}, a first electrode of the light emitting transistor T_{EM} can be connected to a second electrode of the driving transistor T_{DR}, and a scan signal SC can be applied to a gate electrode of the driving transistor T_{DR}. The scan signal SC applied to the gate electrode of the driving transistor T_{DR} can be a direct current power source, and a fixed reference voltage can be applied in every frame.

The second electrode of the driving transistor T_{DR} can be connected to a first electrode of the light emitting transistor T_{EM}, the light emitting device ED can be connected to a second electrode of the light emitting transistor T_{EM}, and a light emitting signal EM can be applied to a gate electrode of the light emitting transistor T_{EM}. The light emitting signal EM applied to the gate electrode of the light emitting transistor T_{EM} can be a pulse width modulation signal (PWM) that changes in every frame.

A first electrode of the light emitting device ED can be connected to the second electrode of the light emitting transistor T_{EM}, and a second electrode of the light emitting device ED can be connected to ground. For example, the first electrode of the light emitting device ED can be an anode electrode and the second electrode of the light emitting device ED can be a cathode electrode.

Each of the driving transistor T_{DR} and the light emitting transistor T_{EM} can be an n-type transistor or a p-type transistor.

The driving transistor T_{DR} can be turned on by the scan signal SC applied from a timing controller T-CON and the light emitting transistor T_{EM} can be turned on by the light emitting signal EM. In this case, a driving current can be applied to the light emitting device ED through the driving transistor T_{DR} and the light emitting transistor T_{EM} by the high potential power supply voltage VDD applied to the first electrode of the driving transistor T_{DR}, and thus the light emitting device ED can emit light.

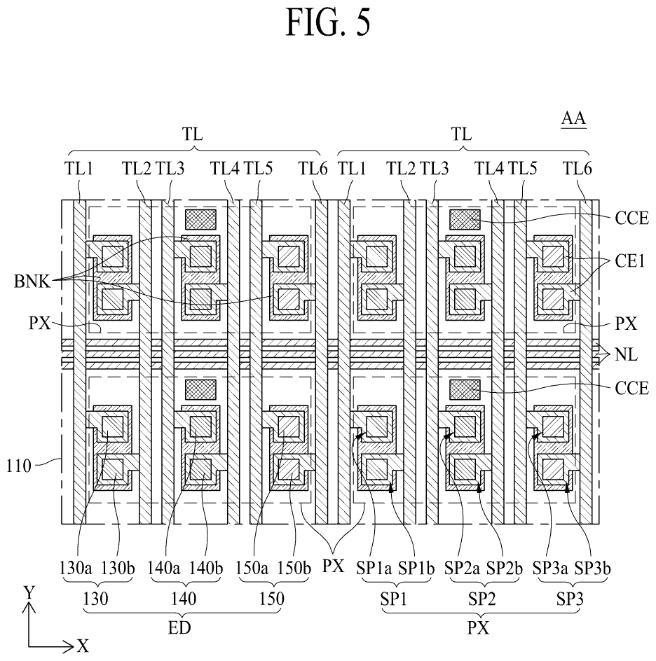

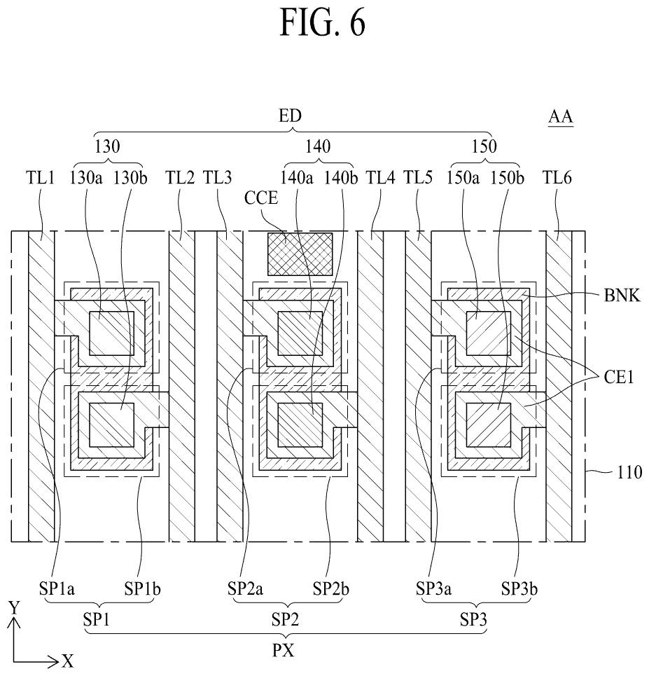

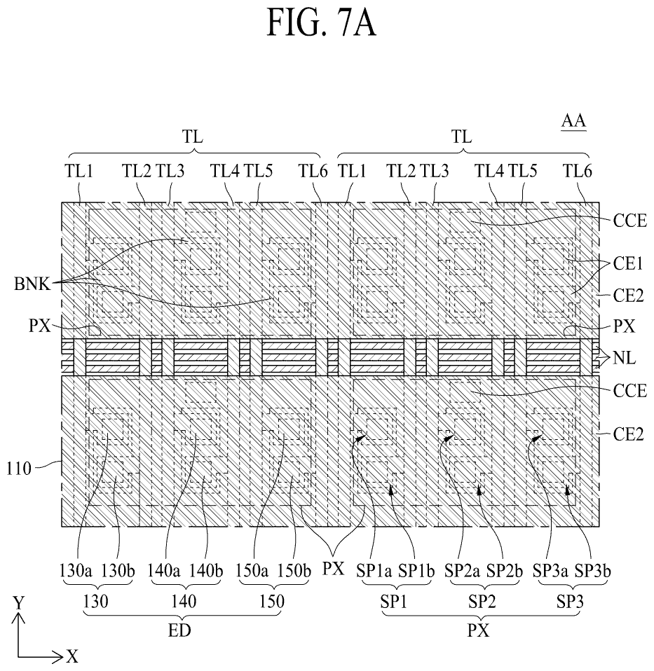

FIGS. 5 to 7B are plan views of a display panel applied to a display apparatus according to an embodiment of the present disclosure. For example, FIG. 5 is an enlarged plan view of a portion of the display area AA including a plurality of pixels, FIG. 6 is an enlarged plan view of a part of the display area AA including one pixel, FIG. 7A is another plan view of the area illustrated in FIG. 5, and FIG. 7B is a plan view illustrating two second electrodes CE2 illustrated in FIG. 7A. A plurality of signal lines TL, a plurality of communication lines NL, a plurality of first electrodes CE1, a plurality of banks BNK, and a plurality of light emitting devices ED are illustrated in FIGS. 5 and 6. FIG. 7A illustrates two second electrodes CE2 added to the plan view illustrated in FIG. 5, and FIG. 7B illustrates two second electrodes CE2 illustrated in FIG. 7A.

Referring to FIGS. 5 to 7B, a plurality of pixels PX including a plurality of sub-pixels can be disposed in the display area AA. Each of the plurality of sub-pixels includes a light emitting device ED and can independently emit light. The plurality of sub-pixels can be configured in a plurality of rows and a plurality of columns and can be disposed in a matrix form.

The plurality of sub-pixels can include a first sub-pixel SP1, a second sub-pixel SP2, and a third sub-pixel SP3. For example, any one of the first sub-pixel SP1, the second sub-pixel SP2, and the third sub-pixel SP3 can be a red sub-pixel, another can be a green sub-pixel, and the other can be a blue sub-pixel. Types of the plurality of sub-pixels are examples, and embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3.

The pair of first sub-pixels SP1 can include a 1ath sub-pixel SP1a and a 1bth sub-pixel SP1b. The pair of second sub-pixels SP2 can include a 2ath sub-pixel SP2a and a 2bth sub-pixel SP2b. The pair of third sub-pixels SP3 can include a 3ath sub-pixel SP3a and a 3bth sub-pixel SP3b. For example, one pixel PX can include the 1ath sub-pixel SP1a, the 1bth sub-pixel SP1b, the 2ath sub-pixel SP2a, the 2bth sub-pixel SP2b, the 3ath sub-pixel SP3a, and the 3bth sub-pixel SP3b.

The plurality of sub-pixels constituting one pixel PX can be variously arranged. For example, in one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. The number and arrangement of the plurality of sub-pixels constituting one pixel PX are examples, and embodiments of the present disclosure are not limited thereto.

The plurality of signal lines TL can be disposed in an area between the plurality of sub-pixels. The plurality of signal lines TL can extend in a column direction between the plurality of sub-pixels. The plurality of signal lines TL can be lines that transmit an anode voltage from the pixel driving circuit PD (showed in FIG. 3) to the plurality of sub-pixels. For example, the signal line TL can be electrically connected to the pixel driving circuit PD and the first electrode CE1 of the sub-pixel. The anode voltage output from the pixel driving circuit PD (for example, from the micro-driver (μDriver)) can be transmitted to the first electrode CE1 of the sub-pixel through the signal line TL.

For example, the first electrode CE1 can be an electrode electrically connected to the anode electrode of the light emitting device ED. The anode voltage transmitted through the signal line TL can be transmitted to the anode electrode of the light emitting device ED through the first electrode CE1. For example, the first electrode CE1 is connected to the anode electrode. Accordingly, in the following description, the first electrode CE1 can mean, as an example, the anode electrode, or can mean, as an example, a separate electrode connected to the anode electrode.

In the display apparatus according to an example of the present disclosure, instead of forming a plurality of transistors and storage capacitors in each of the plurality of sub-pixels, the pixel driving circuit PD in which the plurality of pixel circuits is integrated is used, and thus, a structure of the display apparatus 1000 can be simplified. In addition, because a circuit disposed in each of the plurality of sub-pixels is integrated in one pixel driving circuit PD, high efficiency and low power driving can be possible.

The plurality of signal lines TL can include a first signal line TL1, a second signal line TL2, a third signal line TL3, a fourth signal line TL4, a fifth signal line TL5, and a sixth signal line TL6. Each of the first signal line TL1 and the second signal line TL2 can be electrically connected to the pair of first sub-pixels SP1. Each of the third signal line TL3 and the fourth signal line TL4 can be electrically connected to the pair of second sub-pixels SP2. Each of the fifth signal line TL5 and the sixth signal line TL6 can be electrically connected to the pair of third sub-pixels SP3.

The first signal line TL1 can be disposed at one side of the pair of first sub-pixels SP1, and the second signal line TL2 can be disposed at the other side of the pair of first sub-pixels SP1. The first signal line TL1 can be electrically connected to one of the pair of first sub-pixels SP1, for example, the first electrode CE1 of the 1ath sub-pixel SP1a. The second signal line TL2 can be electrically connected to the remaining first sub-pixel SP1 of the pair of first sub-pixels SP1, for example, the first electrode CE1 of the 1bth sub-pixel SP1b.

The third signal line TL3 can be disposed at one side of the pair of second sub-pixels SP2, and the fourth signal line TL4 can be disposed at the other side of the pair of second sub-pixels SP2. For example, the third signal line TL3 can be disposed adjacent to the second signal line TL2. The third signal line TL3 can be electrically connected to one of the pair of second sub-pixels SP2, for example, the first electrode CE1 of the 2ath sub-pixel SP2a. The fourth signal line TL4 can be electrically connected to the remaining second sub-pixel SP2 of the pair of second sub-pixels SP2, for example, the first electrode CE1 of the 2bth sub-pixel SP2b.

The fifth signal line TL5 can be disposed at one side of the pair of third sub-pixels SP3, and the sixth signal line TL6 can be disposed at the other side of the pair of third sub-pixels SP3. For example, the fifth signal line TL5 can be disposed adjacent to the fourth signal line TL4. The sixth signal line TL6 can be disposed adjacent to the first signal line TL1 connected to the adjacent pixel PX. The fifth signal line TL5 can be electrically connected to one of the pair of third sub-pixels SP3, for example, the first electrode CE1 of the 3ath sub-pixel SP3a. The sixth signal line TL6 can be electrically connected to the remaining third sub-pixel SP3 of the pair of third sub-pixels SP3, for example, the first electrode CE1 of the 3bth sub-pixel SP3b.

The signal line TL can be formed of a conductive material. For example, the signal line TL can be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. For another example, the plurality of signal lines TL can be formed of a multilayer structure including conductive materials. For example, the plurality of signal lines TL can be formed of the multilayer structure in which titanium (Ti), aluminum (Al), titanium (Ti), and indium tin oxide (ITO) are stacked.

The plurality of communication lines NL can be disposed in an area between adjacent pixels PX. The communication line NL can be disposed to extend in a row direction in an area between the adjacent pixels PX. The communication line NL can be disposed in an area between adjacent second electrodes CE2 and may not overlap the adjacent second electrodes CE2. For example, the communication line NL can be a line used for short-range communication such as near field communication (NFC). The communication line NL can function as an antenna.

According to the present disclosure, a bank BNK can be disposed in each of the plurality of sub-pixels. The bank BNK can be a structure in which the plurality of light emitting devices ED is disposed. The plurality of banks BNK can guide positions of the plurality of light emitting devices ED in a transfer process of the plurality of light emitting devices ED. The plurality of light emitting devices ED can be transferred onto the plurality of banks BNK in the transfer process of the plurality of light emitting devices ED. The entire area of the light emitting device ED can overlap the bank BNK. The plurality of banks BNK can be bank patterns or construction, but embodiments of the present disclosure are not limited thereto.

A bank BNK of the first sub-pixel SP1, a bank BNK of the second sub-pixel SP2, and a bank BNK of the third sub-pixel SP3 can be disposed to be spaced apart from each other. The bank BNK of the first sub-pixel SP1, the bank BNK of the second sub-pixel SP2, and the bank BNK of the third sub-pixel SP3 can be configured to be separated. Accordingly, the banks BNK of the first sub-pixel SP1, the second sub-pixel SP2, and the third sub-pixel SP3 to which different types of light emitting devices ED are transferred can be easily identified.

The bank BNK of the 1ath sub-pixel SP1a and the bank BNK of the 1bth sub-pixel SP1b can be connected to each other or can be spaced apart from each other. For example, the bank BNK of the last sub-pixel SP1a and the bank BNK of the 1bth sub-pixel SP1b in which the same light emitting device ED is disposed can be connected or can be separated or spaced apart from each other in consideration of design such as transfer process requirements. Further, the bank BNK of the 2ath sub-pixel SP2a and the bank BNK of the 2bth sub-pixel SP2b can be connected to each other or can be separated or spaced apart from each other. The bank BNK of the 3ath sub-pixel SP3a and the bank BNK of the 3bth sub-pixel SP3b can be connected to each other or can be separated or spaced apart from each other. Accordingly, the bank BNK of the pair of first sub-pixels SP1, the bank BNK of the pair of second sub-pixels SP2, and the bank BNK of the pair of third sub-pixels SP3 can be variously formed.

For example, each of the plurality of banks BNK can be formed of an organic insulating material. Each of the plurality of banks BNK can be formed of a single layer or a multilayer of an organic insulating material. For example, each of the plurality of banks BNK can be formed of a photo resist, a polyimide (PI), an acryl-based material, or the like.

The first electrode CE1 can be disposed in each of the plurality of sub-pixels. The first electrode CE1 can overlap the bank BNK to be disposed on the bank BNK. The first electrode CE1 can be electrically connected to one of the plurality of signal lines TL.

At least a portion of the first electrode CE1 can extend to an outside of the bank BNK to be electrically connected to the signal line TL closest to the first electrode CE1. A portion of the first electrode CE1 can overlap the bank BNK, and the rest of the first electrode CE1 may not overlap the bank BNK.

For example, a portion of the first electrode CE1 of the 1ath sub-pixel SP1a can extend to one side area of the 1ath sub-pixel SP1a to be electrically connected to the first signal line TL1, and a portion of the first electrode CE1 of the 1bth sub-pixel SP1b can extend to the other side area of the 1bth sub-pixel SP1b to be electrically connected to the second signal line TL2. A portion of the first electrode CE1 of the 2ath sub-pixel SP2a can extend to one side area of the 2ath sub-pixel SP2a to be electrically connected to the third signal line TL3, and a portion of the first electrode CE1 of the 2bth sub-pixel SP2b can extend to the other side area of the 2bth sub-pixel SP2b to be electrically connected to the fourth signal line TL4. A portion of the first electrode CE1 of the 3ath sub-pixel SP3a can extend to one side area of the 3ath sub-pixel SP3a to be electrically connected to the fifth signal line TL5, and a portion of the first electrode CE1 of the 3bth sub-pixel SP3b can extend to the other side area of the 3bth sub-pixel SP3b to be electrically connected to the sixth signal line TL6.

The first electrode CE1 is electrically connected to the anode electrode of the light emitting device ED. The anode voltage from the pixel driving circuit PD can be transmitted to the light emitting device ED via the signal line TL and the first electrode CE1. A different voltage can be applied to the first electrode CE1 of each of the plurality of sub-pixels according to an image that is displayed. For example, different voltage can be applied to the first electrodes CE1 of the plurality of sub-pixels. Accordingly, the first electrode CE1 can be referred to as a pixel electrode.

The first electrode CE1 can be formed of a conductive material. For example, the first electrode CE1 can be formed integrally with the signal line TL. For example, the first electrode CE1 can be formed of the same conductive material as the signal line TL. For example, the first electrode CE1 can be formed of one of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like. For another example, the first electrode CE1 can be formed of a multilayer structure of the conductive material. For example, the plurality of first electrodes CE1 can be formed of the multilayer structure in which titanium (Ti), aluminum (Al), titanium (Ti), and indium tin oxide (ITO) are stacked.

The light emitting device ED can be disposed in each of a plurality of sub-pixels. The plurality of light emitting device ED can be any one of a light-emitting diode (LED) and a micro light-emitting diode (Micro LED). The plurality of light emitting devices ED can overlap the bank BNK and the first electrode CE1 to be disposed on the bank BNK and the first electrode CE1. The entire area of the light emitting device ED can overlap the bank BNK and the first electrode CE1.

The light emitting devices ED can be disposed on the first electrode CE1 and can be electrically connected to the first electrode CE1. Accordingly, the light emitting device ED can emit light by using the anode voltage (or the anode current) from the pixel driving circuit PD through the signal line TL and the first electrode CE1.

The plurality of light emitting devices ED can include a first light emitting device 130, a second light emitting device 140, and a third light emitting device 150. The first light emitting device 130 can be disposed in the first sub-pixel SP1. The second light emitting device 140 can be disposed in the second sub-pixel SP2. The third light emitting device 150 can be disposed in the third sub-pixel SP3. For example, one of the first light emitting device 130, the second light emitting device 140, and the third light emitting device 150 can be a red light emitting device, another can be a green light emitting device, and the other can be a blue light emitting device, but embodiments of the present disclosure are not limited thereto. Light of various colors including white can be implemented by combining red light, green light, and blue light emitted from the plurality of light emitting devices ED. Types of the plurality of light emitting devices ED are examples, and embodiments of the present disclosure are not limited thereto.

The first light emitting device 130 can include a 1ath light emitting device 130a disposed in the 1ath sub-pixel SP1a and a 1bth light emitting device 130b disposed in the 1bth sub-pixel SP1b. The second light emitting device 140 can include a 2ath light emitting device 140a disposed in the 2ath sub-pixel SP2a and a 2bth light emitting device 140b disposed in the 2bth sub-pixel SP2b. The third light emitting device 150 can include a 3ath light emitting device 150a disposed in the 3ath sub-pixel SP3a and a 3bth light emitting device 150b disposed in the 3bth sub-pixel SP3b.

The second electrode CE2 can be disposed in each of the plurality of sub-pixels.

The second electrode CE2 can be disposed on the light emitting device ED. The second electrode CE2 can be electrically connected to the pixel driving circuit PD through contact electrodes CCE.

For example, the second electrode CE2 can be electrically connected to the cathode electrode of the light emitting device ED to transmit the cathode voltage from the pixel driving circuit PD to the light emitting device ED. For example, the second electrode CE2 is connected to the cathode electrode. Therefore, in the following description, the second electrode CE2 can refer to a cathode electrode or a separate electrode connected to the cathode electrode.

The same cathode voltage can be applied to the second electrodes CE2 of the plurality of sub-pixels. For example, the same voltage can be applied to the second electrodes CE2 provided in the plurality of sub-pixels. Accordingly, the second electrode CE2 can be referred to as a common electrode.

At least some of the plurality of sub-pixels can share the second electrode CE2. For example, the second electrode CE2 can be provided in at least two sub-pixels. To provide an additional description, the second electrode CE2 can be provided in at least one pixel PX among a plurality of pixels PX disposed in the same row in the horizontal direction (X-axis direction). For example, one second electrode CE2 can be disposed in a plurality of pixels PX. For example, one second electrode CE2 can be disposed in n sub-pixels (n is a natural number). FIGS. 7A and 7B illustrate a display apparatus in which one second electrode CE2 is provided in two sub-pixel disposed in the horizontal direction (X-axis direction).

In this case, the second electrodes CE2 disposed in the plurality of sub-pixels can be spaced apart from each other or separated from each other. For example, the second electrode CE2 connected to the pixels PX of an n-th row and the second electrode CE2 connected to the pixels PX of an n+1th row can be spaced apart from each other or separated from each other. For example, as illustrated in FIGS. 7a and 7b, the plurality of second electrodes CE2 can be spaced apart from each other with the plurality of communication lines NL extending in a row direction interposed therebetween. Accordingly, the number of the plurality of sub-pixels can be greater than the number of the plurality of second electrodes CE2.

The plurality of second electrodes CE2 can be formed of a transparent conductive material. When the plurality of second electrodes CE2 are formed of the transparent conductive material, light emitted from the light emitting device ED is directed to an upper portion of the second electrode CE2. For example, the second electrode CE2 can be formed of the transparent conductive material such as indium tin oxide (ITO), indium zinc oxide (IZO), indium gallium zinc oxide (IGZO), or the like.

A plurality of contact electrodes CCE can be disposed on the substrate 110. For example, the plurality of contact electrodes CCE can be disposed to be spaced apart from a plurality of banks BNK and a plurality of signal lines TL. Each of the plurality of second electrodes CE2 can overlap at least one contact electrode CCE. For example, one second electrode CE2 can overlap a plurality of contact electrodes CCE.

For example, the plurality of contact electrodes CCE can be electrically connected to the second electrode CE2. The contact electrode CCE can be disposed between the substrate 110 and the second electrode CE2 to transfer the cathode voltage transmitted from the pixel driving circuit PD to the second electrode CE2.

When a micro LED is used as the light emitting device ED, a plurality of micro LEDs can be formed in a wafer and the micro LEDs can be transferred to the substrate 110, and thus the display panel 100 can be manufactured. Various defects can occur in the process of transferring the plurality of light emitting devices ED having a micro size from the wafer to the substrate 110. For example, a non-transfer defect in which the light emitting device ED is not transferred can occur in some sub-pixels, and a defect in which the light emitting device ED is transferred out of a correct position due to an alignment error can occur in some sub-pixels. Further, even if the transfer process has proceeded normally, the transferred light emitting device ED itself can have a defect. Accordingly, the plurality of the same light emitting devices ED can be transferred to one sub-pixel in consideration of the defect during the transfer process of the plurality of light emitting devices ED. After the lighting test of the plurality of light emitting devices ED is performed, only one light emitting device ED finally determined to be normal can be used.

For example, the 1ath light emitting device 130a and the 1bth light emitting device 130b can be transferred to one pixel PX, and it is possible to inspect whether there is a defect in the 1ath light emitting device 130a and the 1bth light emitting device 130b. If both of the 1ath light emitting device 130a and the 1bth light emitting device 130b are determined to be normal, only the 1ath light emitting device 130a can be used and the 1bth light emitting device 130b can be not used. As another example, if only the 1bth light emitting device 130b of the 1ath light emitting device 130a and the 1bth light emitting device 130b is determined to be normal, the 1ath light emitting device 130a is not be used and only the 1bth light emitting device 130b can be used. Therefore, even if the plurality of the same light emitting devices ED are transferred to one pixel PX, only one light emitting device ED can be finally used.

In this case, any one of the pair of light emitting devices ED can be referred to as a main or primary light emitting device ED, and the other light emitting device ED can be referred to as a redundancy light emitting device ED. The redundancy light emitting device ED can be an extra light emitting device ED transferred to prepare for a defect in the main light emitting device ED. When the main light emitting device ED is defective, the redundancy light emitting device ED can be used instead of the main light emitting device ED. The main light emitting device ED and the redundancy light emitting device ED are transferred to one pixel PX, thereby minimizing deterioration of display quality due to defects in the main light emitting device ED and the redundancy light emitting device ED.

For example, the 1ath light emitting device 130a, the 2ath light emitting device 140a, and the 3ath light emitting device 150a transferred to one pixel PX can be used as the main light emitting device ED, and the 1bth light emitting device 130b, the 2bth light emitting device 140b, and the 3bth light emitting device 150b can be used as the redundancy light emitting device ED.

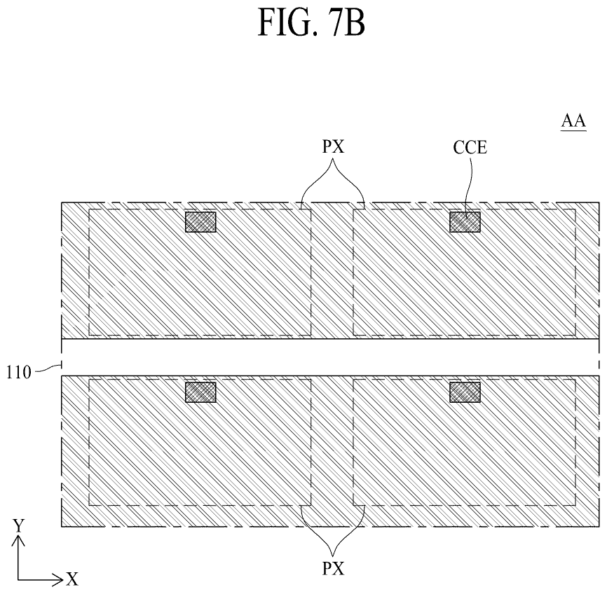

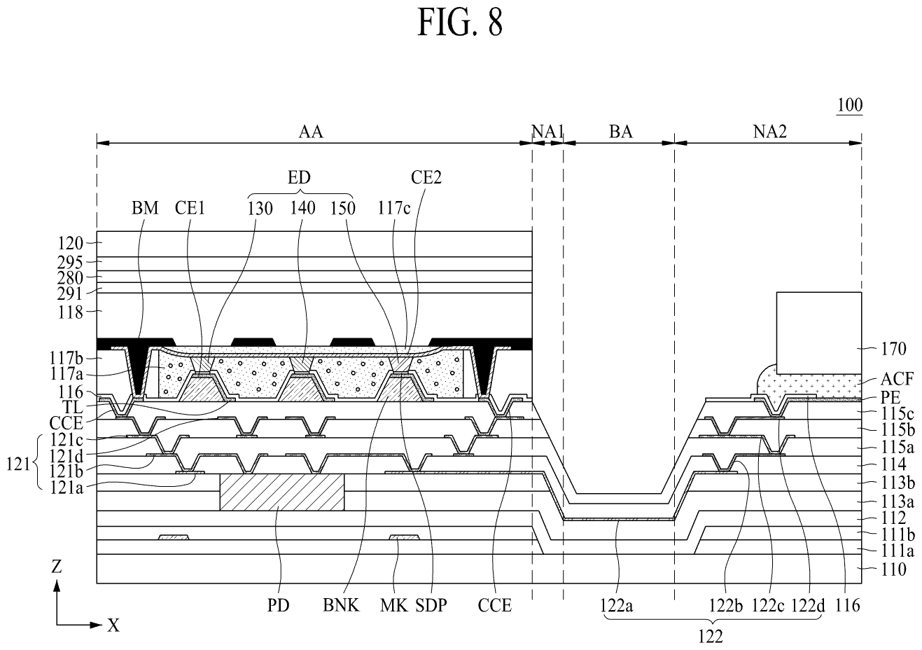

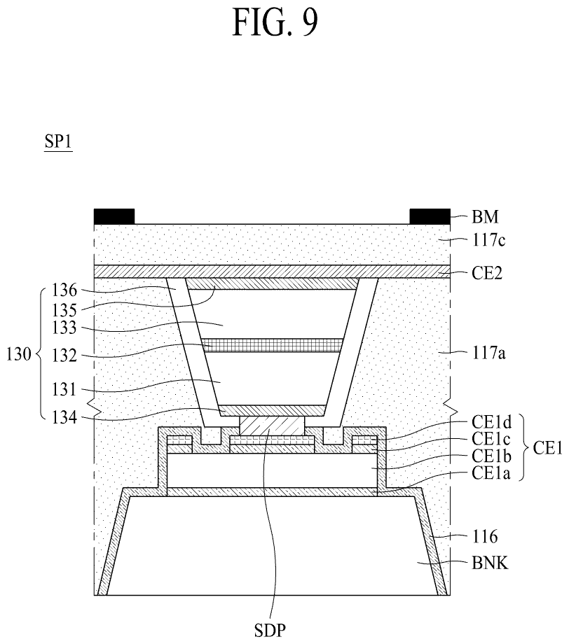

FIG. 8 is an example diagram illustrating a cross-sectional surface of a display panel applied to a display apparatus according to an embodiment of the present disclosure, and FIG. 9 is a cross-sectional view of a light emitting device applied to a display apparatus according to an embodiment of the present disclosure. For example, FIG. 8 is a cross-sectional view of the display area AA, the first non-display area NA1, the bending area BA, and the second non-display area NA2, and FIG. 9 is a cross-sectional view of the light emitting device ED in the display area AA.

Referring to FIG. 8, a first buffer layer 111a and a second buffer layer 111b can be disposed in the remaining area of the substrate 110 except the bending area BA.

The first buffer layer 111a and the second buffer layer 111b can be disposed in the display area AA, the first non-display area NA1, and the second non-display area NA2. The first buffer layer 111a and the second buffer layer 111b can reduce penetration of moisture or impurities through the substrate 110. The first buffer layer 111a and the second buffer layer 111b can be formed of an inorganic insulating material. For example, each of the first buffer layer 111a and the second buffer layer 111b can be formed of a single layer composed of silicon oxide (SiOx) or silicon nitride (SiNx) or a multilayer including at least one of silicon oxide (SiOx) and silicon nitride (SiNx), but embodiments of the present disclosure are not limited thereto.

For example, portions of the first buffer layer 111a and the second buffer layer 111b on the bending area BA can be removed. An upper surface of the substrate 110 disposed in the bending area BA cannot be covered by the first buffer layer 111a and the second buffer layer 111b to be exposed. When the first buffer layer 111a and the second buffer layer 111b made of the inorganic insulating material are removed from the bending area BA, cracks, which can occur during bending, in the first buffer layer 111a and the second buffer layer 111b can be minimized.

A plurality of alignment keys MK can be disposed between the first buffer layer 111a and the second buffer layer 111b. The plurality of alignment keys MK can be formed to identify a position of the pixel driving circuit PD during a manufacturing process of the display panel 100. For example, the plurality of alignment keys MK can align the position of the pixel driving circuit PD transferred onto an adhesive layer 112. However, the plurality of alignment keys MK can be omitted.

An adhesive layer 112 can be disposed on the second buffer layer 111b. The adhesive layer 112 can be disposed in the display area AA, the first non-display area NA1, the bending area BA, and the second non-display area NA2. A portion of the adhesive layer 112 can be removed from the non-display area NA including the bending area BA. For example, the adhesive layer 112 can be formed of any one of an Adhesive polymer, an epoxy resin, a UV curable resin, a polyimide-based resin, an acrylate-based material, a urethane-based material, and a polydimethylsiloxane (PDMS).

In the display area AA, the pixel driving circuit PD can be disposed on the adhesive layer 112. The pixel driving circuit PD can be mounted on the adhesive layer 112 through a transfer process, but embodiments of the present disclosure are not limited thereto.

A first protective layer 113a and a second protective layer 113b can be disposed on the adhesive layer 112 and the pixel driving circuit PD. The first protective layer 113a and the second protective layer 113b can surround a side surface of the pixel driving circuit PD. For example, the second protective layer 113b can cover at least a portion of an upper surface of the pixel driving circuit PD. At least one of the first protective layer 113a and the second protective layer 113b disposed on the bending area BA can be omitted. For example, the first protective layer 113a can be entirely disposed in the display area AA and the non-display area NA. Further, the second protective layer 113b can be partially disposed in the display area AA, the first non-display area NA1, and the second non-display area NA2. Moreover, the second protective layer 113b may not be disposed in the bending area BA.

The first protective layer 113a and the second protective layer 113b can be formed of an organic insulating material. For example, the first protective layer 113a and the second protective layer 113b can be formed of a photo resist, polyimide (PI), a photo acryl-based material, or the like. The first protective layer 113a and the second protective layer 113b can be an overcoating layer or an insulating layer.

According to the present disclosure, a plurality of first connection lines 121 can be disposed on the second protective layer 113b in the display area AA. The first connection line 121 can be a line for electrically connecting the pixel driving circuit PD to other devices. The pixel driving circuit PD can be electrically connected to the signal line TL, the contact electrode CCE or the like through the first connection line 121.

The first connection line 121 can include a 1ath connection line 121a, a 1bth connection line 121b, a 1cth connection line 121c, and a 1dth connection line 121d.

The plurality of 1ath connection lines 121a can be disposed on the second protective layer 113b. The plurality of 1ath connection lines 121a can be electrically connected to the pixel driving circuit PD. The 1ath connection lines 121a can transmit voltages output from the pixel driving circuit PD to the first electrode CE1 or the second electrode CE2.

A third protective layer 114 can be disposed on the second protective layer 113b. The third protective layer 114 can be disposed on the entire display area AA and the non-display area NA. In the bending area BA, the third protective layer 114 can disposed on or cover a side surface of the second protective layer 113b and an upper surface of the first protective layer 113a. The third protective layer 114 can be formed of an organic insulating material. The third protective layer 114 can be formed of a photo resist, polyimide (PI), a photo acryl-based material, or the like. For example, the first protective layer 113a, the second protective layer 113b, and the third protective layer 114 can be formed of the same material, but embodiments of the present disclosure are not limited thereto.

The plurality of 1bth connection lines 121b can be disposed on the third protective layer 114. The 1bth connection lines 121b can be connected to the pixel driving circuit PD through the 1ath connection lines 121a or can be directly connected to the pixel driving circuit PD. For example, a portion of the 1bth connection line 121b can be directly connected to the pixel driving circuit PD through a contact hole of the third protective layer 114. The other portion of the 1bth connection line 121b can be electrically connected to the 1ath connection line 121a through a contact hole of the third protective layer 114. However, embodiments of the present disclosure are not limited thereto. For example, the voltage output from the pixel driving circuit PD can be transmitted to the first electrode CE1 or the second electrode CE2 through a connection line different from the 1bth connection lines 121b.

A first insulating layer 115a can be disposed on the plurality of 1bth connection lines 121b. The first insulating layer 115a can be disposed in the entire display area AA and the non-display area NA, but embodiments of the present disclosure are not limited thereto. The first insulating layer 115a can be formed of an organic insulating material. The first insulating layer 115a can be formed of a photo resist, polyimide (PI), a photo acryl-based material, or the like.

The plurality of 1cth connection lines 121c can be disposed on the first insulating layer 115a. The 1cth connection lines 121c can be electrically connected to the 1bth connection lines 121b. For example, the 1cth connection lines 121c can be electrically connected to the 1bth connection lines 121b through a contact hole of the first insulating layer 115a.

A second insulating layer 115b can be disposed on the plurality of 1cth connection lines 121c. The second insulating layer 115b can be disposed in the remaining area except for the bending area BA. The second insulating layer 115b can be disposed in the display area AA, the first non-display area NA1, and the second non-display area NA2. For example, at least a portion of the second insulating layer 115b disposed in the bending area BA can be removed. The second insulating layer 115b can be formed of an organic insulating material, but embodiments of the present disclosure are not limited thereto. For example, the second insulating layer 115b can be formed of a photo resist, polyimide (PI), a photo acryl-based material, or the like.

The plurality of 1dth connection lines 121d can be disposed on the second insulating layer 115b. The 1dth connection lines 121d can be electrically connected to the 1cth connection lines 121c. For example, the 1dth connection lines 121d can be electrically connected to the 1cth connection lines 121c through a contact hole of the second insulating layer 115b.

The 1dth connection line 121d can be connected to the contact electrode CCE through a contact hole of a third insulating layer 115c, and thus, the contact electrode CCE and the pixel driving circuit PD can be electrically connected to the first connection line 121.

For example, the contact electrode CCE connected to the second electrode CE2 can be electrically connected to the pixel driving circuit PD through the 1dth connection line 121d, the 1cth connection line 121c, the 1bth connection line 121b, and the 1ath connection line 121a.

However, the 1dth connection line 121d can be directly connected to the signal line TL through a contact hole disposed in the third insulating layer 115c, or can be electrically connected to the signal line TL through other additional line or electrode, and thus, the signal line TL and the pixel driving circuit PD can be electrically connected to each other by the first connection line 121.

The signal line TL can be formed of at least one of the 1ath to 1dth connection lines 121a to 121d, or can be connected to the first connection line 121.

A plurality of second connection lines 122 can be disposed on the second protective layer 113b in the non-display area NA. The second connection lines 122 can be a line for transmitting a signal received from the flexible circuit board (or a flexible film) 170 and a printed circuit board 160 to the pixel driving circuit PD of the display area AA.

For example, the plurality of second connection lines 122 can be electrically connected to the plurality of pad electrodes PE to receive signals from flexible circuit boards (or flexible films) 170 and printed circuit boards 160.

For example, the plurality of second connection lines 122 can extend from the pad part PAD toward the display area AA to transmit signals to the lines of the display area AA. In this case, each of the plurality of second connection lines 122 can function as link lines LL (showed in FIG. 3). The second connection line 122 can include a 2ath connection line 122a, a 2bth connection line 122b, a 2cth connection line 122c, and a 2dth connection line 122d.

The plurality of 2ath connection lines 122a can be disposed on the second protective layer 113b. The plurality of 2ath connection lines 122a can extend from the second non-display area NA2 to the bending area BA and the first non-display area NA1. The plurality of 2ath connection lines 122a can transmit signals received from the flexible circuit board (or flexible film) 170 and the printed circuit board 160 to the pixel driving circuit PD of the display area AA. Accordingly, the 2ath connection line 122a can be electrically connected to the pad electrode PE and the pixel driving circuit PD, respectively. For example, the 2ath connection line 122a can extend to the display area AA to be directly connected to the pixel driving circuit PD in the display area AA, or can be electrically connected to the pixel driving circuit PD through other additional line or electrodes. Further, the 2ath connection line 122a can be electrically connected to the pad electrode PE in the second non-display area NA2 through the 2bth connection line 122b, the 2cth connection line 122c, and the 2dth connection line 122d. Therefore, the pixel driving circuit PD and the pad electrode PE can be electrically connected by the second connection line 122.

The plurality of 2bth connection lines 122b can be disposed on the third protective layer 114. 2bth connection lines 122b can be disposed in the second non-display area NA2. The 2bth connection lines 122b can be electrically connected to the 2ath connection lines 122a through a contact hole of the third protective layer 114. Therefore, signals from the flexible circuit board (or flexible film) 170 and the printed circuit board 160 can be transmitted to the 2ath connection lines 122a through the 2bth connection lines 122b.

The 2cth connection line 122c can be disposed on the first insulating layer 115a. The 2cth connection line 122c can be disposed in the second non-display area NA2. The 2cth connection line 122c can be electrically connected to the 2bth connection line 122b through a contact hole of the first insulating layer 115a. Accordingly, signals from the flexible circuit board (or flexible film) 170 and the printed circuit board 160 can be transmitted to the 2ath connection line 122a through the 2cth connection line 122c and the 2bth connection line 122b.

The 2dth connection line 122d can be disposed on the second insulating layer 115b. The 2dth connection line 122d can be disposed in the second non-display area NA2. The 2dth connection line 122d can be electrically connected to the 2cth connection line 122c through a contact hole of the second insulating layer 115b. Accordingly, signals from the flexible circuit board (or flexible film) 170 and the printed circuit board 160 can be transmitted to the 2ath connection line 122a through the 2dth connection line 122d, the 2cth connection line 122c, and the 2bth connection line 122b.

In addition, the 2ath connection line 122a can extend to the display area AA through the bending area BA, and can be electrically connected to the pixel driving circuit PD in the display area AA.

Accordingly, the pad electrode PE provided in the second non-display area NA2 can be electrically connected to the pixel driving circuit PD provided in the display area AA through the 2dth connection line 122d, the 2cth connection line 122c, and the 2bth connection line 122b in the second non-display area NA2, and the 2ath connection line 122a in the bending area BA.

Each of the first connection line 121 and the second connection line 122 can be formed of a conductive material having excellent ductility or various conductive materials used in the display area AA. For example, the second connection line 122 partially disposed in the bending area BA can be formed of a conductive material having excellent ductility, such as gold (Au), silver (Ag), or aluminum (Al). For another example, each of the first connection lines 121 and the second connection lines 122 can be formed of molybdenum (Mo), chromium (Cr), titanium (Ti), nickel (Ni), neodymium (Nd), copper (Cu), an alloy of silver (Ag) and magnesium (Mg), or an alloy thereof, but embodiments of the present disclosure are not limited thereto.

A third insulating layer 115c can be disposed on the plurality of first connection lines 121 and the plurality of second connection lines 122. The third insulating layer 115c can be disposed in the remaining area except for the bending area BA. The third insulating layer 115c can be disposed in the display area AA, the first non-display area NA1, and the second non-display area NA2. At least a portion of the third insulating layer 115c in the bending area BA can be removed. The third insulating layer 115c can be formed of an organic insulating material, but embodiments of the present disclosure are not limited thereto. For example, the third insulating layer 115c can be formed of a photo resist, polyimide (PI), a photo acryl-based material, or the like.

A bank BNK can be disposed on the third insulating layer 115c in the display area AA. The bank BNK can overlap the sub-pixel. The bank BNK may not be disposed in the first non-display area NA1, the second non-display area NA2, and the bending area BA. One or more light emitting devices ED of the same type can be disposed on an upper portion of the bank BNK.

In the display area AA, a plurality of signal lines TLs can be disposed on the third insulating layer 115c. The signal line TL can be disposed between the plurality of banks BNK. For example, the signal line TL can be disposed adjacent to any one of the plurality of banks BNK. The signal line TL can be electrically connected to the first connection line 121, for example, the 1dth connection line 121d.

A plurality of contact electrodes CCE can be disposed on the third insulating layer 115c in the display area AA. The contact electrode CCE can supply the cathode voltage transmitted from the pixel driving circuit PD to the second electrode CE2. The contact electrode CCE can be electrically connected to the first connection line 121, for example, the 1dth connection line 121d.

A first electrode CE1 can be disposed on the bank BNK. For example, the first electrode CE1 can extend from the adjacent signal line TL to an upper portion of the bank BNK. The first electrode CE1 can be disposed on an upper surface of the bank BNK and a side surface of the bank BNK. For example, the first electrode CE1 can extend from the signal line TL on an upper surface of the third insulating layer 115c to the side surface of the bank BNK and the upper surface of the bank BNK. The first electrode CE1 can be integrally formed with the signal line TL.

Referring to FIG. 9, the first electrode CE1 can include a plurality of conductive layers. For example, the first electrode CE1 can include a first conductive layer CE1a, a second conductive layer CE1b, a third conductive layer CE1c, and a fourth conductive layer CE1d.

The first conductive layer CE1a can be disposed on the bank BNK. The second conductive layer CE1b can be disposed on the first conductive layer CE1a. The third conductive layer CE1c can be disposed on the second conductive layer CE1b, and the fourth conductive layer CE1d can be disposed on the third conductive layer CE1c. For example, the first conductive layer CE1a, the second conductive layer CE1b, the third conductive layer CEIc, and the fourth conductive layer CE1d can be formed of titanium (Ti), molybdenum (Mo), aluminum (Al), or an alloy of titanium (Ti) and indium tin oxide (ITO), but embodiments of the present disclosure are not limited thereto.

Some of the plurality of conductive layers included in the first electrode CE1 having high reflection efficiency can be used as an alignment key and/or a reflector for aligning the light emitting device ED. For example, the second conductive layer CE1b among the plurality of conductive layers of the first electrode CE1 can include a reflective material. For example, the second conductive layer CE1b can include aluminum (Al). In this case, the second conductive layer CE1b can be used as a reflective plate. Further, due to a high reflection efficiency of the second conductive layer CE1b, identification can be easily performed in a manufacturing process, and thus an arrangement position or a transfer position of the light emitting device ED can be arranged with respect to the second conductive layer CE1b.

For example, in order to use the second conductive layer CE1b as the reflective plate, the third conductive layer CEIc and the fourth conductive layer CE1d covering the second conductive layer CE1b can be partially removed or etched. Portions of the third and fourth conductive layers CEIc and CE1d disposed on the bank BNK can be removed or etched to expose an upper surface of the second conductive layer CE1b. A central portion and an edge portion of the third and fourth conductive layers CEIc and CE1d on which a solder pattern SDP is disposed can remain, and remaining portions except for the center portion and the edge portion of the third and fourth conductive layers CEIc and CE1d can be removed. The central portion and the edge portion of each of the third conductive layer CEIc made of titanium (Ti) and the fourth conductive layer CE1d made of indium tin oxide (ITO) may not be etched. Thus, another conductive layer of the first electrode CE1 can be prevented from being corroded by a TMAH (Tetra Methyl Ammonium Hydroxide) solution used in a mask process of the first electrode CE1.

The first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has high adhesion to the solder pattern SDP and has corrosion resistance and acid resistance.

The first conductive layer CE1a, the second conductive layer CE1b, the third conductive layer CE1c, and the fourth conductive layer CE1d can be sequentially deposited and then patterned by a photolithography process and an etching process.

Each of the signal line TL, the contact electrode CCE, and the pad electrode PE disposed on the same layer as the first electrode CE1 can be formed of multiple layers of conductive materials, but embodiments of the present disclosure are not limited thereto. For example, each of the signal line TL, the contact electrode CCE, and the pad electrode PE can be formed of multiple layers in which indium tin oxide (ITO), titanium (Ti), aluminum (Al), and titanium (Ti) are stacked.

A solder pattern SDP can be disposed on the first electrode CE1 in each of the plurality of sub-pixels. The solder pattern SDP can bond the light emitting device ED to the first electrode CE1. The first electrode CE1 and the light emitting device ED can be electrically connected to each other through eutectic bonding using the solder pattern SDP, but embodiments of the present disclosure are not limited thereto. For example, when the solder pattern SDP is formed of indium (In), and the anode electrode 134 of the light emitting device ED is formed of gold (Au), the solder pattern SDP and the anode electrode 134 can be bonded to each other by applying heat and pressure in the transfer process of the light emitting device ED. The light emitting device ED can be bonded to the solder pattern SDP and the first electrode CE1 without a separate adhesive member through eutectic bonding. The solder pattern SDP can be formed of indium (In), tin (Sn), or alloys thereof. For example, the solder pattern SDP can be a bonding pad or the like.

A passivation layer 116 can be disposed on the plurality of signal lines TL, the plurality of first electrodes CE1, the plurality of contact electrodes CCE, and the third insulation layer 115c. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE can be removed in the second non-display area NA2. A portion of the passivation layer 116 covering the plurality of contact electrodes CCE can be removed in the display area AA. The passivation layer 116 covering the solder pattern SDP can be removed in the display area AA. The passivation layer 116 can cover the first electrode CE1. The passivation layer 116 can cover a portion of the exposed upper surface of a second conductive layer CE1b.

Because the passivation layer 116 covers the remaining areas while exposing a portion of the plurality of pad electrodes PE, a portion of the plurality of contact electrodes CCE, and a portion of the solder pattern SDP, penetration of moisture or impurities flowing into the light emitting device ED can be reduced. The passivation layer 116 can be formed of a single layer or multiple layers including silicon oxide (SiOx) or silicon nitride (SiNx). For example, the passivation layer 116 can be a protective layer or an insulating layer. The passivation layer 116 can include a hole exposing the solder pattern SDP and holes exposing the contact electrode CCE.

In each of the plurality of sub-pixels, the light emitting device ED can be disposed on the solder pattern SDP. The first light emitting device 130 can be disposed in the first sub-pixel SP1. The second light emitting device 140 can be disposed in the second sub-pixel SP2. The third light emitting device 150 can be disposed in the third sub-pixel SP3.

The light emitting device ED can be formed on silicon wafers by means of metal organic vapor deposition (MOCVD), chemical vapor deposition (CVD), plasma-enhanced chemical vapor deposition (PECVD), molecular beam growth (MBE), hydride vapor deposition (HVPE), or sputtering, but embodiments of the present disclosure are not limited thereto.

The first light emitting device 130 can include an anode electrode 134, a first semiconductor layer 131, an active layer 132, a second semiconductor layer 133, a cathode electrode 135, and an encapsulation layer 136. For example, the encapsulation layer 136 may not be included in the first light emitting device 130.

The first semiconductor layer 131 can be disposed on the solder pattern SDP. The second semiconductor layer 133 can be disposed on the first semiconductor layer 131.

For example, each of the first semiconductor layer 131 and the second semiconductor layer 133 can formed of a compound semiconductor such as a group III-V or a group II-VI, and can be doped with impurities (or dopants). For example, one of the first semiconductor layer 131 and the second semiconductor layer 133 can be a semiconductor layer doped with n-type impurities, and the other can be a semiconductor layer doped with p-type impurities. For example, each of the first semiconductor layer 131 and the second semiconductor layer 133 can be a layer in which an n-type or p-type impurity is doped into a material such as gallium nitride (GaN), gallium phosphide (GaP), gallium arsenic phosphide (GaAsP), aluminum gallium indium phosphide (AlGaInP), indium aluminum phosphide (InAIP), aluminum gallium nitride (AlGaN), aluminum indium nitride (AlInN), aluminum indium gallium nitride (AlInGaN), aluminum gallium arsenic (AlGaAs), gallium arsenic (GaAs). The n-type impurity can be silicon (Si), germanium (Ge), selenium (Se), carbon (C), tellurium (Te), tin (Sn), or the like. The p-type impurity can be magnesium (Mg), zinc (Zn), calcium (Ca), strontium (Sr), barium (Ba), beryllium (Be), or the like,

Each of the first semiconductor layer 131 and the second semiconductor layer 133 can be a nitride semiconductor including the n-type impurity or a nitride semiconductor including the p-type impurity. For example, the first semiconductor layer 131 can be a nitride semiconductor including the p-type impurity, and the second semiconductor layer 133 can be a nitride semiconductor including the n-type impurity.

The active layer 132 can be disposed between the first semiconductor layer 131 and the second semiconductor layer 133. The active layer 132 can emit light by receiving holes and electrons from the first semiconductor layer 131 and the second semiconductor layer 133. For example, the active layer 132 can be formed of one of a single well structure, a multi-well structure, a single quantum well structure, a multi-quantum well (MQW) structure, a quantum dot structure, and a quantum line structure. The active layer 132 can be formed of indium gallium nitride (InGaN), gallium nitride (GaN), or the like.

For another example, the active layer 132 can include a multi-quantum well (MQW) structure having a well layer and a barrier layer having a band gap higher than that of the well layer. For example, the active layer 132 can include InGaN as a well layer, and can include an AlGaN layer as a barrier layer.

The anode electrode 134 can be disposed between the first semiconductor layer 131 and the solder pattern SDP. The anode electrode 134 can electrically connect the first semiconductor layer 131 to the first electrode CE1. The anode voltage output from the pixel driving circuit PD can be applied to the first semiconductor layer 131 through the signal line TL, the first electrode CE1, and the anode electrode 134. The anode electrode 134 can be formed of a conductive material capable of eutectic bonding with the solder pattern SDP. For example, the anode electrode 134 can be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or alloys thereof.

The cathode electrode 135 can be disposed on the second semiconductor layer 133. For example, the cathode electrode 135 can electrically connect the second semiconductor layer 133 to the second electrode CE2. The cathode voltage output from the pixel driving circuit PD can be applied to the second semiconductor layer 133 through the contact electrode CCE, the second electrode CE2, and the cathode electrode 135. The cathode electrode 135 can be formed of a transparent conductive material to allow light emitted from the light emitting device ED to be directed to an upper portion of the light emitting device ED. For example, the cathode electrode 135 can be formed of a material such as indium tin oxide (ITO), indium zinc oxide (IZO), indium gallium zinc oxide (IGZO), or the like.

The encapsulation layer 136 can be disposed on at least a portion of each of the first semiconductor layer 131, the active layer 132, the second semiconductor layer 133, the anode electrode 134, and the cathode electrode 135. For example, the encapsulation layer 136 can surround at least a portion of each of the first semiconductor layer 131, the active layer 132, the second semiconductor layer 133, the anode electrode 134, and the cathode electrode 135.

The encapsulation layer 136 can protect the first semiconductor layer 131, the active layer 132, and the second semiconductor layer 133. The encapsulation layer 136 can be disposed on a side surface of the first semiconductor layer 131, a side surface of the active layer 132, and a side surface of the second semiconductor layer 133.

The encapsulation layer 136 can be disposed on at least a portion of the anode electrode 134 and the cathode electrode 135. For example, the encapsulation layer 136 can be disposed on the edge portion (or one side) of the anode electrode 134 and the edge portion (or one side) of the cathode electrode 135. At least a portion of the anode electrode 134 can be exposed by the encapsulation layer 136, and thus the anode electrode 134 can connect with the solder pattern SDP. For example, at least a portion of the cathode electrode 135 can be exposed by the encapsulation layer 136, and thus the cathode electrode 135 can connect with the second electrode CE2. The encapsulation layer 136 can be formed of an insulating material such as silicon nitride (SiNx) or silicon oxide (SiOx).

For another example, the encapsulation layer 136 can be a layer in which a reflective material is distributed in a resin layer. The encapsulation layer 136 can be manufactured as a reflector having various structures. Light emitted from the active layer 132 can be reflected upward by the encapsulation layer 136 so that light extraction efficiency can be improved. In this case, the encapsulation layer 136 can be a reflective layer.

The light emitting device ED has been described as a vertical structure, but embodiments of the present disclosure are not limited thereto. For example, the light emitting device ED can have a lateral structure or a flip chip structure.

Although the first light emitting device 130 has been described above with reference to FIG. 9, the second light emitting device 140 and the third light emitting device 150 can have substantially the same structure as the first light emitting device 130. For example, each of the second light emitting device 140 and the third light emitting device 150 can have substantially the same configuration as the first semiconductor layer 131, the active layer 132, the second semiconductor layer 133, the anode electrode 134, the cathode electrode 135, and the encapsulation layer 136.

According to the present disclosure, as illustrated in FIGS. 8 and 9, a first optical layer 117a surrounding the plurality of light emitting devices ED can be disposed in the display area AA. For example, the first optical layer 117a can cover the side surfaces of the light emitting devices ED and the side surfaces of the plurality of banks BNK. The first optical layer 117a can cover a portion of the passivation layer 116. The first optical layer 117a can be disposed between the second electrode CE2, the passivation layer 116, and the plurality of light emitting devices.

The first optical layer 117a can be disposed between the plurality of light emitting devices ED included in one pixel PX and cover the plurality of light emitting devices ED included in one pixel PX. Further, the first optical layer 117a can be disposed between the plurality of banks BNK included in one pixel PX and cover the plurality of light emitting devices ED included in one pixel PX. For example, the first optical layer 117a can extend in the first direction, and the plurality of first optical layers 117a can be spaced apart from each other in the second direction in a plan view. For example, the first optical layer 117a can be disposed between the passivation layer 116 and the second electrode CE2 to surround the side surface of the light emitting device ED and the side surface of the bank BNK. The first optical layer 117a can be referred to as a diffusion layer, a sidewall diffusion layer, or the like. In the following description, the first direction can be the X-axis direction illustrated in FIG. 5, and the second direction can be the Y-axis direction illustrated in FIG. 5. For example, the first direction and the second direction are different directions. Accordingly, in the following description, reference numeral X can be assigned to the first direction and reference numeral Y can be assigned to the second direction.

The first optical layer 117a can include an organic insulating material in which fine particles are distributed. For example, the first optical layer 117a can be formed of siloxane in which fine metal particles such as titanium dioxide (TiO₂) particles are distributed. Light from the plurality of light emitting devices ED can be scattered by fine particles distributed in the first optical layer 117a and emitted to an outside of the display panel 100. Accordingly, the first optical layer 117a can improve extraction efficiency of light emitted from the plurality of light emitting devices ED.

The first optical layer 117a can be disposed in each of the plurality of pixels PX or can be disposed in some pixels PX disposed in the same row. For example, the first optical layer 117a can be disposed in each of the plurality of pixels PX. Further, the plurality of pixels PX can share one first optical layer 117a. For another example, each of the plurality of sub-pixels can separately include a first optical layer 117a.

The second optical layer 117b can be disposed on the passivation layer 116 in the display area AA. For example, the second optical layer 117b can surround the first optical layer 117a. For example, the second optical layer 117b can be in contact with a side surface of the first optical layer 117a. For example, the second optical layer 117b can be disposed in an area between the plurality of pixels PX. However, embodiments of the present disclosure are not limited thereto. The second optical layer 117b can be referred to as a diffusion layer, a window diffusion layer, or the like.

The second optical layer 117b can be formed of an organic insulating material, but embodiments of the present disclosure are not limited thereto. The second optical layer 117b can be formed of the same material as the first optical layer 117a, but embodiments of the present disclosure are not limited thereto. For example, the first optical layer 117a can include fine particles, and the second optical layer 117b may not include fine particles. For example, the second optical layer 117b can be formed of siloxane.

A thickness of the first optical layer 117a can be less than a thickness of the second optical layer 117b. Accordingly, in a plan view, an area in which the first optical layer 117a is disposed can include a concave portion recessed from an upper surface of the second optical layer 117b.

The second electrode CE2 can be disposed on the first optical layer 117a and the second optical layer 117b. The second electrode CE2 can be electrically connected to the plurality of contact electrodes CCE through a contact hole in the second optical layer 117b. The second electrode CE2 can be disposed on a plurality of light emitting devices ED. The second electrode CE2 can include a transparent conductive oxide such as indium tin oxide (ITO) or indium zinc oxide (IZO). The second electrode CE2 can be disposed to be in contact with the cathode electrode 135. The second electrode CE2 can overlap the entire first optical layer 117a, and can overlap a portion of the second optical layer 117b.

The second electrode CE2 can extend continuously in the first direction X of the substrate 110. Accordingly, the second electrode CE2 can be connected in common to at least two pixels PX arranged in the first direction X of the substrate 110. For example, the second electrode CE2 can be connected in common to at least two pixels PX.

The second electrode CE2 can be provided on upper ends of the first optical layer 117a, the second optical layer 117b, and the light emitting device ED. An area in which the first optical layer 117a is disposed can include a concave portion recessed inwardly from the upper surface of the second optical layer 117b. Accordingly, because a first portion of the second electrode CE2 disposed on the first optical layer 117a is disposed along the concave portion, the first portion of the second electrode CE2 disposed on the first optical layer 117a can be disposed at a lower position than a second portion of the second electrode CE2 disposed on the second optical layer 117b.

A third optical layer 117c can be disposed on the second electrode CE2. The third optical layer 117c can be disposed to overlap a plurality of light emitting devices ED and the first optical layer 117a. In this case, the third optical layer 117c may not to overlap the second optical layer 117b. Because the third optical layer 117c is disposed on the second electrode CE2 and a plurality of light emitting devices ED, the third optical layer 117c can improve a spot Mura that can occur in some of a plurality of light emitting devices ED. For example, when the plurality of light emitting devices ED is transferred on the substrate 110 of the display panel 100, a region in which a gap between the plurality of light emitting devices ED is not uniform due to a process deviation, or the like can occur. When the gap between the plurality of light emitting devices ED is not uniform, a light emitting area of each of the plurality of light emitting devices ED can be non-uniformly disposed, and thus a spot (or mura) can be recognized by a user. Because the third optical layer 117c for uniformly diffusing light is formed on an upper portion of the plurality of light emitting devices ED, it is possible to reduce visibility of light emitted from some light emitting devices ED as spots (or mura). Therefore, because the light emitted from the plurality of light emitting devices ED is uniformly diffused by the third optical layer 117c and extracted to the outside of the display panel 100, the luminance uniformity of the display apparatus can be improved.

The third optical layer 117c can be formed of an organic insulating material in which fine particles are distributed, but embodiments of the present disclosure are not limited thereto. For example, the third optical layer 117c can be formed of siloxane in which fine metal particles such as titanium dioxide (TiO₂) particles are distributed. However, the third optical layer 117c can be formed of the same material as the first optical layer 117a. The third optical layer 117c can be referred to as a diffusion layer, an upper diffusion layer, or the like.

Light from the plurality of light emitting devices ED can be scattered by fine particles distributed in the third optical layer 117c and emitted to the outside of the display panel 100. The third optical layer 117c can evenly mix the light emitted from the plurality of light emitting devices ED to further improve luminance uniformity of the display apparatus. In addition, light extraction efficiency of the display apparatus can be improved by the light scattered from the plurality of fine particles, and thus the display apparatus can be driven at a low power.

In the display area AA, a black matrix BM can be disposed on the second electrode CE2, the first optical layer 117a, the second optical layer 117b, and the third optical layer 117c. For example, the black matrix BM can fill a contact hole in the second optical layer 117b. Because the black matrix BM can cover the display area AA, color mixture of light of the plurality of sub-pixels and reflection of external light can be reduced. For example, because the black matrix BM is also disposed within a contact hole in which the second electrode CE2 and the contact electrode CCE are connected to each other, light leakage between the plurality of adjacent sub-pixels can be prevented.

The black matrix BM is not provided on an upper end of the light emitting device ED. Accordingly, light generated from the light emitting device ED can be output to the outside.

The black matrix BM can be formed of an opaque material, but embodiments of the present disclosure are not limited thereto. For example, the black matrix BM can be formed of an organic insulating material to which a black pigment or a black dye is added.

As illustrated in FIG. 8, a cover layer 118 can be disposed on the black matrix BM in the display area AA. The cover layer 118 can protect a device under the cover layer 118. For example, the cover layer 118 can be formed of an organic insulating material, but embodiments of the present disclosure are not limited thereto. For example, the cover layer 118 can be formed of a photo resist, polyimide (PI), a photo acryl-based material, or the like. The cover layer 118 can be referred to as an overcoating layer, an insulating layer, or the like.

A polarizing layer 280 can be disposed on the cover layer 118 via a first adhesive layer 291. A cover member 120 can be disposed on the polarizing layer 280 via a second adhesive layer 295. For example, the first adhesive layer 291 and the second adhesive layer 295 can include an optically clear adhesive (OCA), an optically clear resin (OCR), a pressure sensitive adhesive (PSA) or the like, but embodiments of the present disclosure are not limited thereto.

According to the present disclosure, the plurality of pad electrodes PE can be disposed on the third insulating layer 115c in the second non-display area NA2. For example, a portion of the plurality of pad electrodes PE can be exposed by the passivation layer 116. For example, the pad electrode PE can be electrically connected to the 2d connection line 122d through a contact hole of the third insulating layer 115c.

An adhesive film ACF can be disposed on the plurality of pad electrodes PE. The adhesive film ACF can be an adhesive layer in which conductive balls are distributed in an insulating material. When heat or pressure is applied to the adhesive film ACF, the conductive ball can be electrically connected to the pad electrode in a region to which heat or pressure is applied, and thus the conductive ball can have conductive characteristics. An adhesive film ACF can be disposed between the plurality of pad electrodes PE and the flexible circuit board (or flexible film) 170, so that a flexible circuit board (or flexible film) 170 can be attached to or bonded to the plurality of pad electrodes PE. For example, the adhesive film ACF can be an anisotropic conductive film (ACF).

The flexible circuit board (or flexible film) 170 can be disposed on the adhesive film ACF. The flexible circuit board (or flexible film) 170 can be electrically connected to the plurality of pad electrodes PE through the adhesive film ACF. Therefore, signals output from the flexible circuit board (or flexible film) 170 and the printed circuit board 160 can be transmitted to the pixel driving circuit PD of the display area AA through the pad electrode PE, the 2dth connection line 122d, the 2cth connection line 122c, the 2bth connection line 122b, and the 2ath connection line 122a.

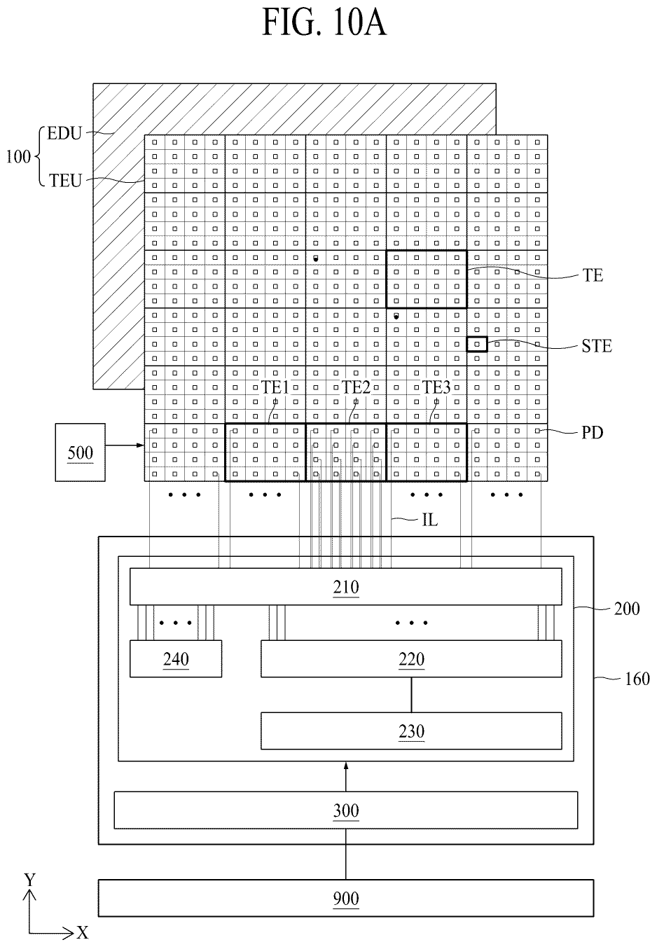

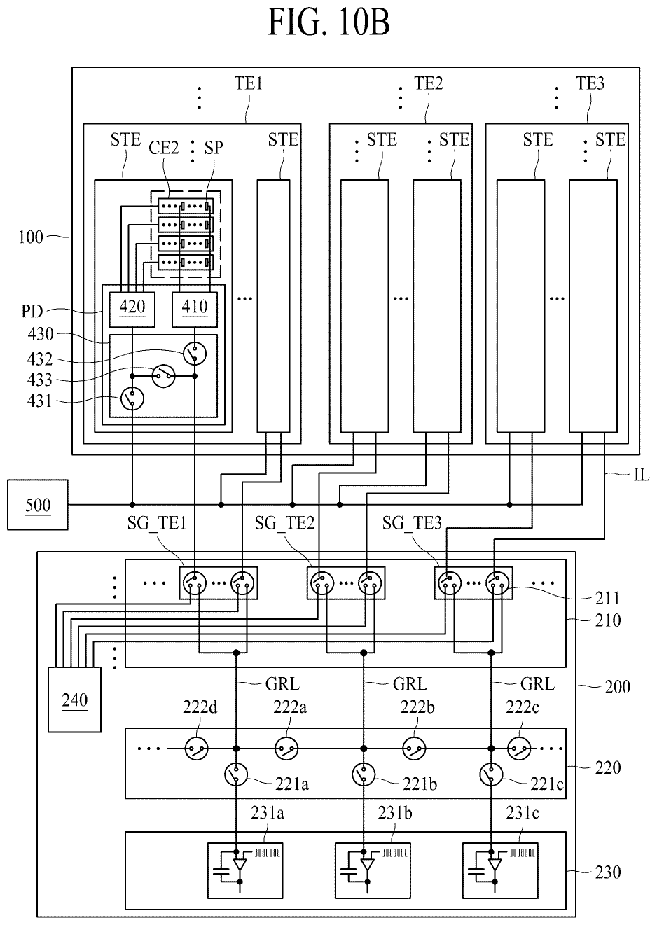

FIG. 10A is an example diagram illustrating a structure of a touch electrode part and a display driver applied to a display apparatus according to an embodiment of the present disclosure, and FIG. 10B is an example diagram illustrating a structure of the display driver illustrated in FIG. 10A in detail. In the following descriptions, details that are the same as or similar to details described with reference to FIGS. 1 to 9 are omitted or briefly described.

The display apparatus according to an embodiment of the present disclosure, as illustrated in FIG. 10A, can include a display panel 100 on which an imaged is displayed and a display driver 200 for supplying image signals and control signals to the pixel driving circuit PD in the display panel 100 during a display period and determining whether the display panel 100 is touched using touch sensing signals transmitted from pixel driving circuits PD provided in the display panel 100 during a touch sensing period.

Further, the display apparatus according to an embodiment of the present disclosure can further include a timing controller 300, a power supply part, a memory, etc., as described with reference to FIGS. 1 and 2, in addition to the display panel 100 and the display driver 200. In this case, the display driver 200 can be included in the timing controller 300.

The display driver 200 and the timing controller 300 can be provided on the printed circuit board 160.

The power supply part can supply power of various levels to the display panel 100, the display driver 200, and the timing controller 300. In particular, the power supply part can perform a function of supplying a cathode voltage to the second electrode CE2. To this end, the power supply part can include a cathode voltage supply part 500. However, the cathode voltage supply part 500 can be provided independently of the power supply part.

As described above, the display panel 100 can include the substrate 110 including the display area AA and the non-display area NA, the pixel driving circuits PD provided in the display area on the substrate 110, the insulating layer on the pixel driving circuits PD, the banks BNK on the insulating layer, the first electrodes CE1 connected to the pixel driving circuits PD, the light emitting devices ED provided on the first electrodes, and the second electrodes CE2 provided on the light emitting devices ED.

Here, the insulating layer can be formed as a single layer, but can include a plurality of layers. For example, the insulating layer can include the first insulating layer 115a, the second insulating layer 115b, and the third insulating layer 115c.

The first electrode CE1 can be provided in each of the banks BNK. The light emitting device ED can be provided on the first electrode CE1. The second electrode CE2 can be disposed on the light emitting device ED.

Each of the light emitting devices ED can be driven by any one of the pixel driving circuits PD. Each of the pixel driving circuits PD can be connected to at least two light emitting devices ED to drive at least two light emitting devices ED. Each of the second electrodes CE2 can be connected to at least two light emitting devices ED.

Some of the plurality of sub-pixels can be covered by the second electrode CE2. For example, the first light emitting device 130, the second light emitting device 140, and the third light emitting device 150 provided in the first sub-pixel SP1, the second sub-pixel SP2, and the third sub-pixel SP3 can be covered by one second electrode CE2.

However, as illustrated in FIGS. 7A and 7B, sub-pixels SP included in two or more pixels PX can be covered by one second electrode CE2.

At least two second electrodes CE2 can be connected to each of the pixel driving circuits PD. For example, the first light emitting device 130, the second light emitting device 140, and the third light emitting device 150 provided in one pixel PX can be connected to one second electrode CE2. Further, when the pixel driving circuit PD drives at least two pixels PX, at least two second electrodes CE2 can be connected to the pixel driving circuit PD. For example, when the pixels PX arranged in a 16×16 form are connected to the pixel driving circuit PD, 16 second electrodes CE2 can be connected to the pixel driving circuit PD.

In this case, the display panel 100 can include a light emitting device part EDU including pixel driving circuits PD and light emitting devices ED, and a touch electrode part TEU including at least two second electrodes CE2.

For example, in the display panel 100 illustrated in FIG. 8, the substrate 110, the buffer layers 111a and 111b, the adhesive layer 112, the pixel driving circuit PD, the protective layers 113a, 113b and 114, the insulating layers 115a, 115b, and 115c, the first connection line 121, the bank BNK, the first electrodes CE1, the light emitting devices ED, and the optical layers 117a and 117b can be included in the light emitting device part EDU.

In addition, in the display panel 100 illustrated in FIG. 8, the second electrodes CE2 can be included in the touch electrode part TEU.

Further, in the display panel 100 illustrated in FIG. 8, the black matrix BM, the third optical layer 117c, and the cover layer 118 can be other components included in the display panel 100. However, hereinafter, for convenience of description, the black matrix BM, the third optical layer 117c, and the cover layer 118 can be included in the light emitting device part EDU.

To provide an additional description, as described with reference to FIG. 1, the display apparatus 1000 according to an embodiment of the present disclosure can include a display panel 100, a polarizing layer 280, an adhesive layer 290, a cover member 120, a support substrate 190, a flexible circuit board 170, and a printed circuit board 160, and the display panel 100 can include various layers as illustrated in FIG. 8.

In this case, various layers included in the display panel 100 can be divided into the light emitting device part EDU and the touch electrode part TEU.

The light emitting device part EDU can include various layers as described above, and in particular, can include light emitting devices ED.

The touch electrode part TEU can include at least two second electrodes CE2.

In this case, the pixel driving circuits PD can be substantially included in the light emitting device part EDU, and can drive the first electrodes CE1 and the second electrodes CE2. However, for convenience of description, in FIG. 10A, the pixel driving circuits PD are included in the touch electrode part TEU.

In the following description, the second electrodes CE2 controlled by one pixel driving circuit PD are referred to as a sub-touch electrode STE.

In addition, in the following description, a configuration including at least one sub-touch electrode STE and corresponding to one touch coordinate is referred to as a touch electrode TE.

For example, the sub-touch electrode STE can be connected to the pixel driving circuit PD, and the sub-touch electrode STE can include at least two second electrodes CE2. As described above, when the pixels PX arranged in the form of 16×16 are connected to the pixel driving circuit PD, the sub-touch electrode STE can include 16 second electrodes CE2.

One pixel driving circuit PD controlling one sub-touch electrode STE can be connected to the display driver 200, as illustrated in FIG. 10A.

For example, the pixel driving circuit PD can be connected to the display driver 200 through the image signal line IL. For example, the image signal line IL is connected to the pixel driving circuit PD.

The pixel driving circuit PD can connect the image signal line IL to the first electrodes CE1 or the second electrodes CE2.

Hereinafter, for convenience of description, a display apparatus according to the present disclosure will be described by taking as an example a touch electrode TE including four sub-touch electrodes STE provided along the first direction X and four sub-touch electrodes STE provided along the second direction Y, as illustrated in FIG. 10A. However, depending on the structure or resolution of the display panel 100, the touch electrode TE provided on the left side of the display panel 100 or the touch electrode TE provided on the right side of the display panel 100 can include three sub-touch electrodes STE provided along the first direction X and four sub-touch electrodes STE provided along the second direction Y. For example, in the display panel 100, each of the touch electrodes TE provided on the right side or the left side of the display panel 100 can include three sub-touch electrodes STE provided along the first direction X and four sub-touch electrodes STE provided along the second direction Y.

To provide an additional description, in the following description, the touch electrode TE can include 16 sub-touch electrodes STE. However, the number of sub-touch electrodes STE included in the touch electrode TE can be variously changed based on the structure and resolution of the display panel 100.

In this case, the display driver 200 can include a data driver that generates image signals to be supplied to the pixel driving circuit PD and a touch driver for sensing a touch.

For example, the display driver 200 can generate image signals to be supplied to the pixel driving circuit PD and supply the image signals to the pixel driving circuit PD.

To this end, each of the pixel driving circuits PD corresponding to all the sub-touch electrodes STE included in the touch electrode part TEU can be connected to the display driver 200 through the image signal line IL.

In this case, power required by the pixel driving circuit PD can be transmitted from the power supply part to the pixel driving circuit PD through the display driver 200, or can be directly transmitted from the power supply part to the pixel driving circuit PD.

Further, cathode voltage required to drive the light emitting devices ED can be transmitted from the cathode voltage supply part 500 to the pixel driving circuit PD through the display driver 200, or can be directly transmitted from the cathode voltage supply part 500 to the pixel driving circuit PD. Hereinafter, for convenience of description, a display apparatus in which a cathode voltage is directly transmitted from the cathode voltage supply part 500 to the pixel driving circuit PD will be described as an example of a display apparatus according to the present disclosure.

Furthermore, the display driver 200 can supply a touch driving signal to the pixel driving circuit PD and sense a touch on the display panel 100 by using a touch sensing signal received from the pixel driving circuit PD.

In this case, the touch coordinates can be determined by the display driver 200, or can be determined by the timing controller 300 or the external system 900.

First, the structure and function of the display panel 100 will be described as follows. Hereinafter, details that are the same as or similar to those described with reference to FIGS. 1 to 9 will be omitted or briefly described.

The display panel 100 can include a light emitting device part EDU including pixel driving circuits PD and light emitting devices ED, and a touch electrode part TEU including at least two second electrodes CE2.

Light can be output from the light emitting device part EDU, and accordingly, an image can be displayed.

The touch electrode part TEU includes at least two touch electrodes TE. The touch electrode TE can include at least one sub-touch electrode STE, and can correspond to one touch coordinate. In a display apparatus according to an embodiment of the present disclosure, the size of the touch electrode TE can be variously changed based on the mode of the display apparatus. The touch electrode TE illustrated in FIG. 10A can be a touch electrode TE of a minimum unit applied to the display apparatus according to an embodiment of the present disclosure. For example, the touch electrode TE illustrated in FIG. 10A can correspond to one touch coordinate in a contact touch sensing period to be described below. In a hover touch sensing period to be described below, a first touch electrode TE1 and a second touch electrode TE2 illustrated in FIG. 10A can perform the function of one touch electrode TE, or the first touch electrode TE1, the second touch electrode TE2, and a third touch electrode TE3 illustrated in FIG. 10A can perform the function of one touch electrode TE.

The touch electrode TE can include at least two second electrodes CE2 connected to the pixel driving circuit PD. The second electrodes CE2 controlled by one pixel driving circuit PD are referred to as sub-touch electrodes STE.

Each of the at least two second electrodes CE2 can extend along a first direction X of the substrate 110, and at least two second electrodes CE2 can be provided along a second direction Y different from the first direction X.

When a cathode voltage is supplied to any one of the at least two second electrodes CE2, light can be output from light emitting devices ED connected to second electrode CE2 to which the cathode voltage is supplied.

For example, a period in which an image is displayed on the display panel 100 is referred to as a display period, and during the display period, a cathode voltage can be supplied to the cathode electrode 135 through the second electrode CE2. The light emitting device ED can output light using a cathode voltage supplied through the cathode electrode 135 and an anode voltage supplied to the anode electrode 134.

When at least two second electrodes CE2 are used as one touch electrode TE, a touch driving signal can be simultaneously supplied to the at least two second electrodes CE2.

For example, a period during which a touch is detected on the display panel 100 is referred to as the touch sensing period, and during the touch sensing period, each of the pixel driving circuits PD can simultaneously supply a touch driving signal received from the display driver 200 to the second electrodes CE2. In this case, the display driver 200 can detect a touch on the display panel 100 by using touch sensing signals received through the pixel driving circuit PD from the second electrodes CE2.

The touch sensing period in which a touch is detected can include a contact touch sensing period in which a touch by an object in contact with the display area is detected and a hover touch sensing period in which a touch by an object spaced apart from the display area is detected.

For example, a touch by an object in contact with the display area is referred to as a contact touch, and a touch by an object spaced apart from the display area is referred to as a hover touch.

In addition, the contact touch refers to a touch when a user's finger or pen contacts the display panel 100, and the hover touch refers to a touch when a user's finger, palm, or hand blade is spaced apart from the upper surface of the display panel 100.

Second, the structure and function of the pixel driving circuit PD will be described as follows. Hereinafter, details that are the same as or similar to those described with reference to FIGS. 1 to 9 will be omitted or briefly described.

In the display period in which an image is displayed, image signals corresponding to light emitting signals EM to be supplied to a gate of light emitting transistors T_{EM} provided in the pixel driving circuit PD can be supplied to the pixel driving circuit PD through the image signal line IL. The image signals can be generated by the image signal generation part 240 included in the display driver 200. The image signal generation part 240 can be a data driver.

Image signals generated by the display driver 200 are transmitted to the pixel driving circuit PD through the image signal line IL, and the pixel driving circuit PD can generate light emitting signals EM by using the image signals. Accordingly, light can be output from the light emitting devices ED.

In addition, the display driver 200 can transmit image signals to each of the image signal lines IL during the display period.

During the touch sensing period in which a touch is detected, touch sensing signals transmitted from the second electrodes CE2 can be output to an image signal line.

For example, during the touch sensing period, the pixel driving circuit PD can supply the touch driving signal transmitted from the display driver 200 to the second electrodes CE2, and transmit the touch sensing signal received from the second electrodes CE2 to the display driver 200 through the image signal line IL. This function can be performed simultaneously in each of the pixel driving circuits PD.

In order to perform the function as described above, the pixel driving circuit PD can include a cathode electrode driving part 420 that supplies a cathode voltage or a touch driving signal to the second electrodes CE2, a sub-pixel driving part 410 that generates light emitting signals EM, and a switching part 430 that connects the image signal line IL to the cathode electrode driving part 420 or the sub-pixel driving part 410.

The cathode electrode driving part 420 can sequentially supply the cathode voltage transmitted from the cathode voltage supply part 500 to the second electrodes CE2 during the display period, and can simultaneously supply the touch driving signal transmitted from the display driver 200 through the image signal line IL to the second electrodes CE2 during the touch sensing period.

To this end, the cathode electrode driving part 420 can include switches connected to the second electrodes CE2, and a connection structure of the switches can be variously changed.

The sub-pixel driving part 410 can change image signals transmitted from the display driver 200 through the signal line IL into light emitting signals EM during the display period, and can supply the light emitting signals EM to gates of the light emitting transistors T_{EM}.

To this end, the sub-pixel driving part 410 can include at least one pixel circuit PC.

The switching part 430 can include a cathode voltage switch 431 that is connected between the cathode voltage supply part 500 supplying the cathode voltage and the cathode electrode driving part 420, an image signal switch 432 that connects the image signal line IL to the sub-pixel driving part 410 or separates the image signal line IL from the sub-pixel driving part 410, and a mode switch 433 that is connected between a switch connection line CL connecting the cathode voltage switch 431 and the cathode electrode driving part 500 and the image signal line IL.

The cathode voltage switch 431 can connect the cathode voltage supply part 500 to the cathode electrode driving part 420 during the display period. Accordingly, the cathode voltage can be supplied to the second electrodes CE2 during the display period.

The cathode voltage switch 431 can be turned off during the touch sensing period. Accordingly, the cathode voltage cannot be supplied from the cathode voltage supply part 500 to the cathode electrode driving part 420.

The image signal switch 432 can connect the image signal line IL to the sub-pixel driving part 410 during the display period. Accordingly, the image signals transmitted from the display driver 200 through the image signal line IL can be transmitted to the sub-pixel driving part 410 during the display period, and the sub-pixel driving part 410 can generate light emitting signals EM by using the image signals.

The image signal switch 432 can separate the sub-pixel driving part 410 from the image signal line IL during the touch sensing period. Accordingly, the touch driving signal supplied through the image signal line IL during the touch sensing period is not transmitted to the sub-pixel driving part 410.

The mode switch 433 can be turned off during the display period. Accordingly, the image signal line IL can be connected to the sub-pixel driving part 410 during the display period. Accordingly, the image signals transmitted from the display driver 200 through the image signal line IL can be transmitted to the sub-pixel driving part 410 during the display period.

The mode switch 433 can be turned on during the touch sensing period. Accordingly, the image signal line IL can be connected to the cathode electrode driving part 420 during the display period. Accordingly, during the touch sensing period, the touch driving signal transmitted from the display driver 200 through the image signal line IL can be transmitted to the cathode electrode driving part 420, and the touch sensing signal transmitted from the cathode electrode driving part 420 can be transmitted to the display driver 200 through the image signal line IL.

Each of the cathode voltage switch 431, the image signal switch 432, and the mode switch 433 can be turned on or off depending on a control signal transmitted from the timing controller 300.

Third, the structure and function of the display driver 200 will be described as follows. Hereinafter, details that are the same as or similar to those described with reference to FIGS. 1 to 9 will be omitted or briefly described.

The display driver 200 can supply image signals to the image signal line IL or determine whether there is a touch on the display panel 100 by using a touch sensing signal transmitted from the second electrodes CE2 through the image signal line IL.

For example, the display driver 200 can supply image signals to the pixel driving circuit PD through the image signal line IL during the display period. The display driver 200 can supply a touch driving signal to the pixel driving circuit PD through the image signal line IL during the touch sensing period, and can determine whether to touch by using a touch sensing signal transmitted from the pixel driving circuit PD through the image signal line IL.

The second electrodes CE2 driven by the at least one pixel driving circuit PD can form a touch electrode TE. The touch sensing period in which a touch is detected can include a contact touch sensing period in which a touch by an object in contact with the display area AA is detected and a hover touch sensing period in which a touch by an object spaced apart from the display area AA is detected.

In this case, the display driver 200 can determine whether there is a touch in at least two touch electrodes TE corresponding to one coordinate by using touch sensing signals received from the at least two touch electrodes TE during the hover touch sensing period. For example, during the hover touch sensing period, the at least two touch electrodes TE can function as one touch electrode corresponding to one coordinate.

In addition, during the contact touch sensing period, the display driver 200 can use the touch sensing signal received from the touch electrode TE to determine whether there is a touch at the touch electrode TE corresponding to one coordinate.

The size of the touch electrode recognized as one touch coordinate in the display driver during the hover touch sensing period can be larger than the size of the touch electrode recognized as one touch coordinate in the display driver during the contact touch sensing period.

For example, during the contact touch sensing period, the display driver 200 can determine whether there is a touch on the touch electrode TE corresponding to one touch coordinate by using a touch sensing signal received from at least one pixel driving circuit. During the hover touch sensing period, the display driver 200 can determine whether a touch occurs on a touch electrode corresponding to a touch coordinate, by using touch sensing signals received from a greater number of pixel driving circuits than the number of pixel driving circuits that transmit touch sensing signals during a contact touch sensing period.

Moreover, the size of the touch electrode TE recognized as a touch coordinate in the display driver 200 during the hover touch sensing period can be larger than the size of the touch electrode TE recognized as a touch coordinate in the display driver 200 during the contact touch sensing period.

For example, during the contact touch sensing period, the display driver 200 can recognize each of the first touch electrodes TE1, the second touch electrode TE2, and the third touch electrode TE3 illustrated in FIGS. 10A and 10B as a touch electrode. Accordingly, a touch coordinate can be given to an area corresponding to each of the first touch electrode TE1, the second touch electrode TE2, and the third touch electrode TE3. In this case, the touch electrode part TEU illustrated in FIG. 10A can include 30 (=5 (number of touch electrodes provided along the first direction)×6 (number of touch electrodes provided along the second direction)) touch electrodes. For convenience of description, reference numerals are illustrated only on the first touch electrode TE1, the second touch electrode TE2, and the third touch electrode TE3 in FIG. 10A.

However, during the hover touch sensing period, the display driver 200 can recognize at least two of the first touch electrode TE1, the second touch electrode TE2, and the third touch electrode TE3 illustrated in FIG. 10A as a touch electrode. Accordingly, one touch coordinate can be applied to an area corresponding to at least two of the first touch electrode TE1, the second touch electrode TE2, and the third touch electrode TE3. Even in the remaining area of the touch electrode part TEU illustrated in FIG. 10A, a touch coordinate can be applied to an area corresponding to the adjacent at least two touch electrodes TE.

Therefore, the size of the touch electrode TE recognized as a touch coordinate during the hover touch sensing period can be larger than the size of the touch electrode TE recognized as a touch coordinate during the contact touch sensing period.

Accordingly, the size of the touch sensing signal corresponding to a coordinate received during the hover touch sensing period can be larger than the size of the touch sensing signal corresponding to a coordinate received during the contact touch sensing period.

As the size of the touch sensing signal increases during the hover touch sensing period, the sensitivity to sense the hover touch can be improved. Accordingly, whether a hover touch is present can be accurately determined.

To perform the function as described above, as illustrated in FIGS. 10A and 10B, the display driver 200 can include an image signal generation part 240 that generates image signals, a touch determination part 230 that generates touch driving signals and determines whether there is a touch on the display panel 100 using touch sensing signals received from the image signal lines ILs, a signal switching part 210 that connects the image signal lines IL to the image signal generation part or the touch determination part 230, and a group switching part 220 provided between the signal switching part 210 and the touch determination part 230.

The image signal generation part 240 can generate image signals by using input image signals and control signals received from the timing controller 300.

The signal switching part 210 includes signal switches 211 connected to the image signal lines ILs. At least two signal switches 211 can be connected to the group switching part 220 through a group line GRL.

Accordingly, each of the signal switches 211 can be connected to an image signal line IL, an image signal generation part 240, and a group line GRL.

At least two image signal lines IL connected to at least two signal switches 211 can be connected to at least two pixel driving circuits PD, and second electrodes CE2 driven by at least two pixel driving circuits PD can form a touch electrode.

For example, in FIG. 10B, each of at least two pixel driving circuits PD driving the second electrodes CE2 included in the first touch electrode TE1 can be connected to the image signal line IL, and each of the image signal lines IL can be connected to the signal switch 211.

Accordingly, at least two image signal lines IL connected to at least two pixel driving circuits PD can be connected to at least two signal switches 211.

In this case, the second electrodes CE2 driven by the pixel driving circuits PD connected to the group line GRL through the signal switches 211 can form a touch electrode TE having the smallest size among the touch electrodes TE used in a display apparatus according to an embodiment of the present disclosure.

For example, a touch electrode TE having the smallest size among the touch electrodes TE can be used during the contact touch sensing period.

To provide an additional description, as described above, during the contact touch sensing period, each of the first touch electrode TE1, the second touch electrode TE2, and the third touch electrode TE3 illustrated in FIGS. 10A and 10B can be recognized as one touch electrode TE.

In this case, in FIG. 10B, the signal switches 211 connected to the one group line GRL can be included in a switch group SG. In FIG. 10B, the switch group SG connected to the first touch electrode TE1 can be a first switch group SG_TE1, a switch group SG connected to the second touch electrode TE2 can be a second switch group SG_TE2, and a switch group SG connected to the third touch electrode TE3 can be a third switch group SG_TE3. For example, when the first switch group SG_TE1, the second switch group SG_TE2, and the third switch group SG_TE3 need not be distinguished, the first switch group SG_TE1, the second switch group SG_TE2, and the third switch group SG_TE3 can be collectively referred to as a switch group SG.

The signal switches 211 can be controlled by a control signal transmitted from the timing controller 300.

The group switching part 220 can include at least two group switches 221 connected to at least two group lines GRL connected to the signal switching part 210 and connection switches 222 provided between at least two group lines GRL. In this case, each of the connection switches 222 can be provided between two group lines GRL adjacent to each other.

For example, as illustrated in FIG. 10B, each of the group switches 221 can be connected between the group line GRL and the touch determination part 230, and each of the connection switches 222 can be provided between two group lines GRL adjacent to each other.

The group switches 221 and the connection switches 222 can be controlled by a control signal transmitted from the timing controller 300.

The touch determination part 230 can include at least two determination parts 231 connected to at least two group switches 221.

In the following description, when it is not necessary to distinguish the determination parts 231, a reference numeral 231 can be assigned to each of the determination parts. However, when the determination parts need to be divided into a first determination part, a second determination part, and a third determination part, a reference numeral 231a is assigned to the first determination part, a reference numeral 231b is assigned to the second determination part, and a reference numeral 231c is assigned to the third determination part.

Further, when it is not necessary to distinguish the group switches 221, a reference numeral 221 can be assigned to each of the group switches. However, when the group switches need to be distinguished into a first group switch, a second group switch, and a third group switch, a reference numeral 221a is assigned to the first group switch, a reference numeral 221b is assigned to the second group switch, and a reference numeral 221c is assigned to the third group switch.

In this case, the first group switch 221a can be connected to the first determination part 231a, the second group switch 221b can be connected to the second determination part 231b, and the third group switch 221c can be connected to the third determination part 231c.

In addition, when it is not necessary to distinguish the connection switches 222, a reference numeral 222 can be given to each of the connection switches. However, when the connection switches need to be distinguished into a first connection switch, a second connection switch, a third connection switch, and a fourth connection switch, a reference numeral 222a is given to the first connection switch, a reference numeral 222b is given to the second connection switch, a reference numeral 222c is given to the third connection switch, and a reference numeral 222d is given to the fourth connection switch.

In this case, the first connection switch 222a can be connected between the first group switch 221a and the second group switch 221b, the second connection switch 222b can be connected between the second group switch 221b and the third group switch 221c, the third connection switch 222c can be connected between the third group switch 221c and another group switch provided on the right side of the third group switch 221c in FIG. 10B, and the fourth connection switch 222d can be connected between the first group switch 221a and another group switch provided on the left side of the first group switch 221a in FIG. 10B.

Each of the determination parts 231 can include a comparator (or amplifier) including three terminals, as illustrated in FIG. 10B. The three terminals can include a first terminal, a second terminal, and a third terminal.

For example, a touch driving signal can be received through the first terminal, a converter for converting analog information related to a touch into digital information can be connected to the second terminal, and the third terminal can be connected to the image signal line IL through the group switch 221. In this case, a capacitor can be connected between the second terminal and the third terminal.

During the touch sensing period, a touch driving signal is received through the first terminal, and the touch driving signal received through the first terminal can be transmitted to the second electrodes CE2 through the third terminal and the image signal line IL.

If there is no touch, the magnitude of the voltage charged in a capacitor between the second terminal and the third terminal can be within a preset reference range. However, if there is a touch, the magnitude of the voltage charged in the capacitor between the second terminal and the third terminal can be out of the reference range.

Therefore, the digital information output from the converter can be changed depending on the magnitude of the voltage charged in the capacitor.

Therefore, whether or not a touch is made can be determined by analyzing the digital information output from the converter.

A specific structure of the determination part 231 for determining whether to touch can be variously changed according to a method of determining whether to touch.

The determination parts 231 can be controlled by a control signal received from the timing controller 300.

In this case, at least two determination parts 231 can be driven during the contact touch sensing period to determine whether the display panel 100 is touched.

For example, during the contact touch sensing period, all determination parts 231 can be driven, all group switches 221 can be turned on, all connection switches 222 can be turned off, all signal switches 211 can be turned on, all mode switches 433 can be turned on, all image signal switches 432 can be turned off, and all cathode voltage switches 431 can be turned off.

Therefore, during the contact touch sensing period, the touch driving signal generated by the determination part 231 can be transmitted to the second electrodes CE2 through the group switch 221, the group line GRL, the signal switches 211, the image signal lines ILs, and the mode switches 433.

In addition, the touch sensing signal sensed by the second electrodes CE2 can be transmitted to the determination part 231 through the mode switch 433, the image signal line IL, the signal switch 211, the group line GRL, and the group switch 221.

Accordingly, a touch can be detected in each of all the determination parts 231. For example, a touch can be detected in each of the determination parts 231 corresponding to the first touch electrode TE1, the second touch electrode TE2, and the third touch electrode TE3, and accordingly, a touch in each of the first touch electrode TE1, the second touch electrode TE2, and the third touch electrode TE3 can be detected.

For example, during the hover touch sensing period, at least one of the at least two determination parts can be driven to determine whether the display panel 100 is touched.

Therefore, during the hover touch sensing period, only some determination parts 231 can be driven.

For example, during the hover touch sensing period, when the first touch electrode TE1 and the second touch electrode TE2 illustrated in FIGS. 10A and 10B are recognized as a touch electrode corresponding to one touch coordinate, and the third touch electrode TE3 and another touch electrode TE are recognized as another touch electrode corresponding to one coordinate, the first determination part 231a corresponding to the first touch electrode TE1 and the third determination part 231c corresponding to the third touch electrode TE3 can be driven, and the second determination part 231b corresponding to the second touch electrode TE2 may not be driven.

However, as described below, even if the second determination part 231b corresponding to the second touch electrode TE2 is driven, because the group switch 221 connected to the second determination part 231b is turned off, all determination parts 231 can be driven even during the hover touch sensing period.

Hereinafter, for convenience of description, a method of driving a display apparatus according to an embodiment of the present disclosure will be described, taking as an example a display apparatus in which the second determination part 231b is not driven during the hover touch sensing period.

Accordingly, during the hover touch sensing period, the first determination part 231a and the third determination part 231c can be driven, and the second determination part 231b may not be driven.

In this case, the first group switch 221a connected to the first determination part 231a and the third group switch 221c connected to the third determination part 231c can be turned on, and the second group switch 221b connected to the second determination part 231b can be turned off.

Further, the first connection switch 222a connected between the first group switch 221a and the second group switch 221b can be turned on, the second connection switch 222b connected between the second group switch 221b and the third group switch 221c can be turned off, the third connection switch 222c connected between the third group switch 221c and a group switch provided on the right side of the third group switch 221c in FIG. 10B can be turned off, and the fourth connection switch 222d connected between the first group switch 221a and a group switch provided on the left side of the first group switch 221a in FIG. 10B can be turned off.

In this case, all signal switches 211 can be turned on, all mode switches 433 can be turned on, all image signal switches 432 can be turned off, and all cathode voltage switches 431 can be turned off.

Accordingly, during the hover touch sensing period, the touch driving signal generated by the first determination part 231a can be transmitted to the second electrodes CE2 provided in the first touch electrode TE1 through the first group switch 221a, the group line GRL connected to the first group switch 221a, the signal switches 211 included in the first switch group SG_TE1, the image signal lines IL connected to the first switch group SG_TE1, and all the mode switches 433 provided in the first touch electrode TE1.

Moreover, the touch driving signal generated by the first determination part 231a can be transmitted to the second electrode CE2 through the first group switch 221a, the first connection switch 222a, the group line GRL connected to the second group switch 221b, the signal switches 211 included in the second switch group SG_TE2, the image signal lines IL connected to the second switch group SG_TE2, and all the mode switches 433 provided in the second touch electrode TE2.

In this case, the touch sensing signal sensed by the second electrodes CE2 provided in the first touch electrode TE1 can be transmitted to the first determination part 231a through the mode switches 433 provided in the first touch electrode TE1, the image signal lines ILs connected to the first touch electrode TE1, the signal switches 211 provided in the first switch group SG_TE1, the group line GRL connected to the first switch group SG_TE1, and the first group switch 221a.

Further, the touch sensing signal sensed by the second electrodes CE2 provided in the second touch electrode TE2 can be transmitted to the first determination part 231a through the mode switches 433 provided in the second touch electrode TE2, the image signal lines IL connected to the second touch electrode TE2, the signal switches 211 provided in the second switch group SG_TE2, the group line GRL connected to the second switch group SG_TE2, the first connection switch 222a, and the first group switch 221a.

Thus, it can be determined whether a touch is made on the first touch electrode TE1 and the second touch electrode TE2. In this case, one touch coordinate can be assigned to an area corresponding to the first touch electrode TE1 and the second touch electrode TE2.

In addition, each of the first touch electrode TEL and the second touch electrode TE2 can be used as a touch electrode having a touch coordinate during the contact touch sensing period, and the first touch electrode TE1 and the second touch electrode TE2 can be used as a touch electrode having a touch coordinate during the hover touch sensing period.

Therefore, the size of the touch electrode corresponding to one touch coordinate during the hover touch sensing period can be larger than the size of the touch electrode corresponding to one touch coordinate during the contact touch sensing period.

When the size of the touch electrode corresponding to one touch coordinate increases, the number and size of touch sensing signals received from the touch electrode can increase, thereby improving touch sensitivity.

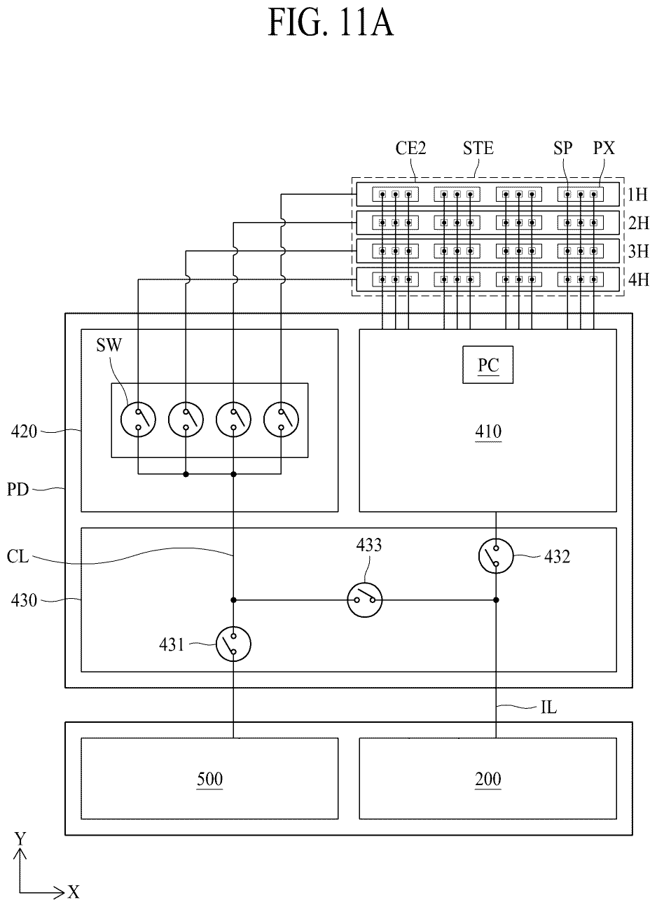

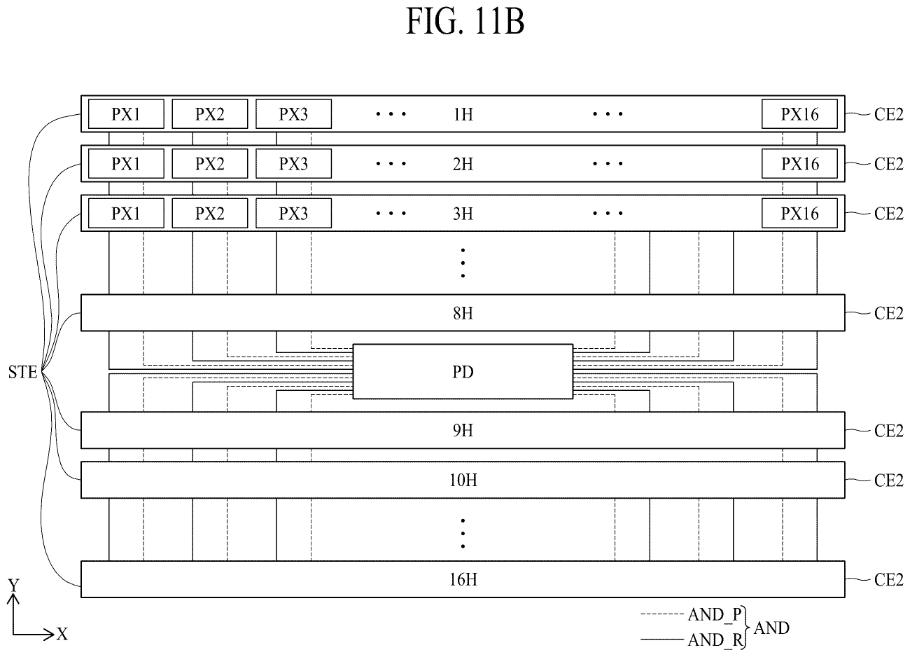

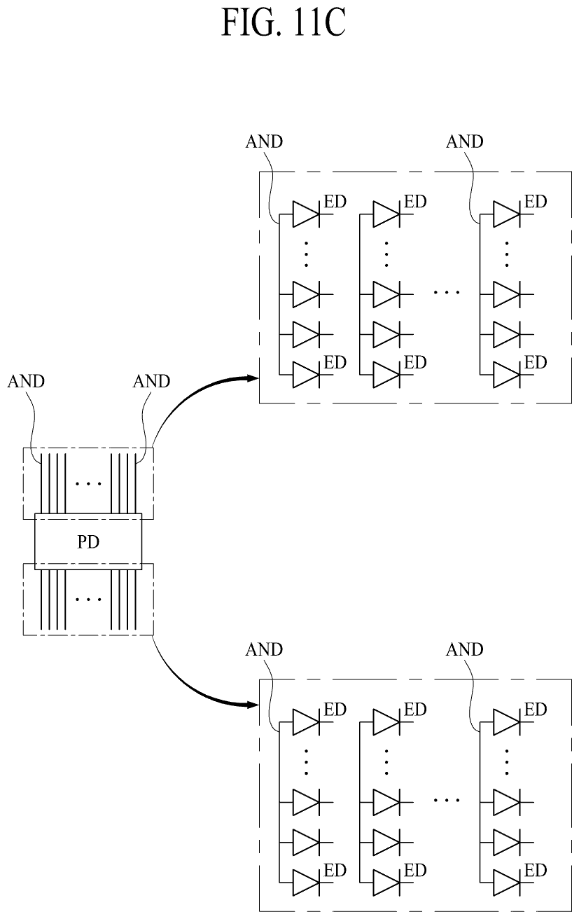

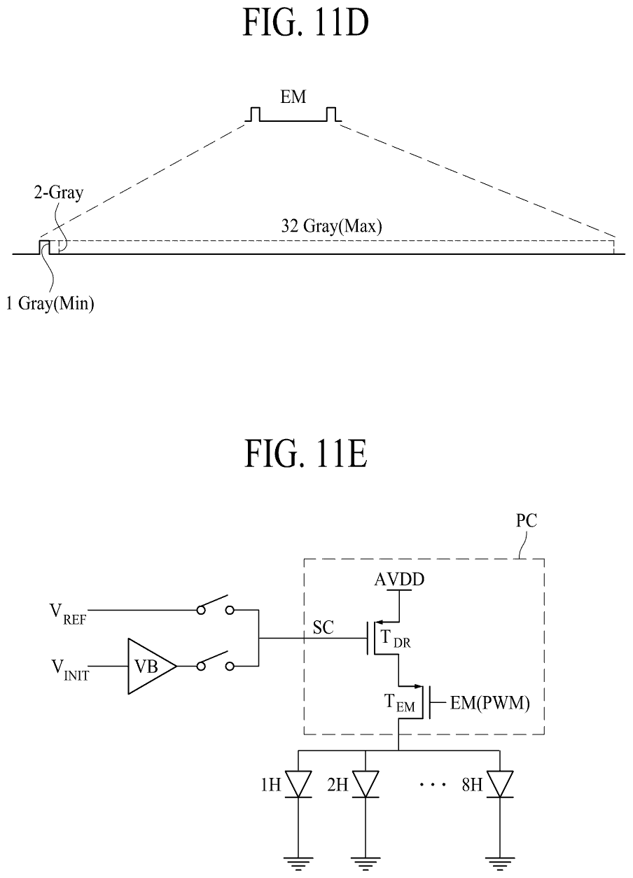

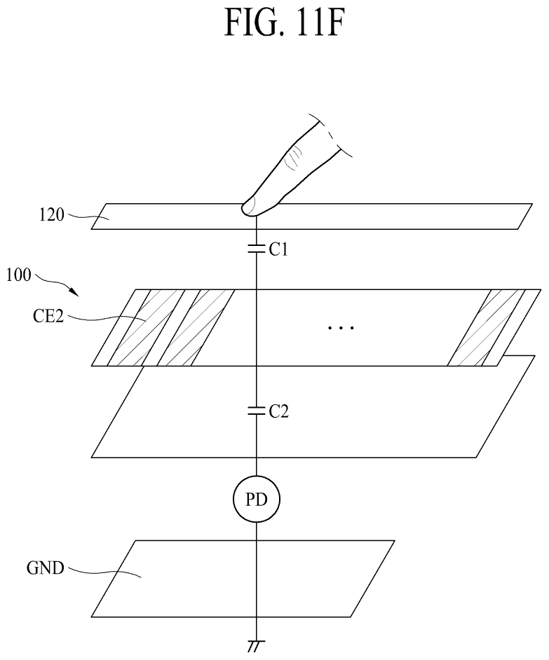

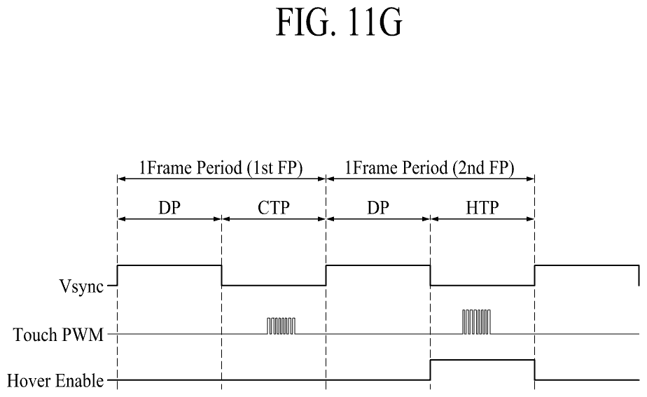

FIG. 11A is an example diagram illustrating structures of a sub-touch electrode and a pixel driving circuit applied to a display apparatus according to an embodiment of the present disclosure, FIG. 11B is an example diagram illustrating a connection structure of a sub-touch electrode and a pixel driving circuit applied to a display apparatus according to an embodiment of the present disclosure, and FIG. 11C is an example diagram illustrating a connection relationship between a pixel driving circuit and light emitting devices applied to a display apparatus according to an embodiment of the present disclosure.

In the following descriptions, details that are the same as or similar to details described with reference to FIGS. 1 to 10B will be omitted or briefly described.

As illustrated in FIG. 11A, the pixel driving circuit PD can include a sub-pixel driving part 410 for supplying anode voltages to anode electrodes 134 provided in the sub-pixels SP, a cathode electrode driving part 420 for supplying a cathode voltage or a touch driving signal to a second electrode CE2 shared in at least two sub-pixels SP, and a switching part 430.

As described above, the second electrodes CE2 controlled by one pixel driving circuit PD are referred to as sub-touch electrode STE.

The sub-touch electrode STE can include at least two second electrode CE2.

As described above, at least two light emitting devices ED can be connected to one pixel driving circuit PD. In addition, one second electrode CE2 can be connected to at least two light emitting devices ED.

Hereinafter, for convenience of description, a display apparatus including a pixel driving circuit PD to which 16 pixels PX having a 4×4 shape are connected, as illustrated in FIG. 11A, is described as an example of a display apparatus according to an embodiment of the present disclosure. In addition, in the display apparatus illustrated in FIG. 11A, pixels PX arranged in a 4×4 shape are connected to the pixel driving circuit PD, but in the display apparatus according to an embodiment of the present disclosure, pixels PX arranged in a 4N×4M (N and M are natural numbers) form can be connected to the pixel driving circuit PD. For example, in FIG. 11B, pixels PX arranged in a 16×16 shape are connected to the pixel driving circuit PD.

For example, as illustrated in FIG. 11A, the pixel driving circuit PD can be connected to four pixels PX provided along the first direction X and four pixels PX provided along the second direction Y.

In this case, one second electrode CE2 controlled by the pixel driving circuit PD can be connected to the light emitting devices DE provided in at least two sub-pixels SP.

In particular, the second electrode CE2 can be connected to at least two light emitting devices DE provided along the first direction X of the display panel 100, and at least two second electrodes CE2 provided along the second direction Y can be separated from each other.

When four pixels PX are provided along the first direction X, and one pixel PX includes three sub-pixels SP, 12 sub-pixels PX can be provided along the first direction X.

In this case, when the second electrode CE2 provided along the first direction X is shared by the two sub-pixels SP, six second electrodes CE2 can be provided along the first direction X.

Accordingly, one pixel driving circuit PD can be connected to 24 (=6×4) second electrodes CE2.

However, hereinafter, for convenience of description, as illustrated in FIG. 11A, the display apparatus according to an embodiment of the present disclosure will be described by taking as an example a display apparatus in which four pixels PX provided along the first direction X are connected to one second electrode CE2.

In this case, the pixel driving circuit PD can be connected to the four second electrodes CE2.

Hereinafter, for convenience of description, a display apparatus according to an embodiment of the present disclosure is described using a pixel driving circuit PD to which 16 pixels PX having a 4×4 shape are connected and a second electrode CE2 connected to four pixels PX along the first direction X, as illustrated in FIG. 11A.

First, the sub-pixel driving part 410 will be described as follows

Hereinafter, as illustrated in FIGS. 4 and 11A, a circuit provided in the sub-pixel driving part 410 for driving at least one light emitting device ED is referred to as a pixel circuit PC. For example, the pixel circuit PC can include a driving transistor T_{DR} and a light emitting transistor T_{EM}, as illustrated in FIG. 4. In this case, a scan signal SC capable of turning on the driving transistor T_{DR} can be supplied to a gate of the driving transistor T_{DR}. The scan signal SC can be a direct current power source capable of continuously turning on the driving transistor T_{DR}. For example, a fixed reference voltage VREF can be supplied to the gate of the driving transistor T_{DR} for each frame.

A light emitting signal EM can be supplied to the gate of the light emitting transistor T_{EM}. The light emitting signal EM can be a pulse width modulation (PWM) signal. The amount of current supplied to the light emitting device ED can be controlled by the light emitting signal EM, and thus, light having various brightness can be output from the light emitting device ED. At least one pixel circuit PC can be provided in the sub-pixel driving part 410.

In this case, a high potential power supply voltage VDD can be supplied to the first electrode of the driving transistor T_{DR} provided in the pixel circuit PC. The high potential power supply voltage VDD can be supplied from a power part provided outside the pixel driving circuit PD.

The scan signal SC and the light emitting signal EM can be transmitted from a control signal generation part provided outside the pixel driving circuit PD. For example, the scan signal SC and the light emitting signal EM can be transmitted from a control signal generation part included in the timing controller 300. In this case, the light emitting signal EM can be generated in the sub-pixel driving part 410 by using image signals transmitted from the timing controller 300.

For example, as illustrated in FIG. 11A, when four pixels PX connected to the pixel driving circuit PD are provided in one row extending along the first direction X, 16 pixels PX can be provided in four rows 1H, 2H, 3H, and 4H.

To provide an additional description, each of the four rows can be provided along the first direction X, and the four rows can be spaced apart along the second direction Y.

In this case, in order to output light from the light emitting devices ED provided in the first row 1H, light emitting signals EM and scan signals can be supplied to pixel circuits PC connected to the light emitting devices ED provided in the first row 1H.

As described above, the scan signal SC can be a direct current (DC) power source capable of continuously turning on the driving transistor T_{DR}, and the light emitting signal EM can be a pulse width modulation (PWM) signal.

The light emitting transistor T_{EM} can be turned on by the scan signal SC, and thus, the high potential power supply voltage VDD can be supplied to the anode electrode 134 of the light emitting device ED through the driving transistor T_{DR}, the light emitting transistor T_{EM}, and the first electrode CE1.

In this case, as described above, the light emitting signal EM applied to the gate electrode of the light emitting transistor T_{EM} can be a pulse width modulation (PWM) signal, and the pulse width of the light emitting signals EM supplied to the pixel circuits PC connected to the anode electrodes 134 of the light emitting devices ED provided in the first row 1H can be variously set depending on the brightness of light output from the light emitting devices ED.

For example, the pulse width of the light emitting signal EM supplied to the pixel circuit PC connected to the light emitting device outputting high-brightness light can be greater than the pulse width of the light emitting signal EM supplied to the pixel circuit PC connected to the light emitting device outputting low-brightness light.

In this case, when a high-level pulse is supplied to the gate of the light emitting transistor T_{EM}, the light emitting transistor T_{EM} can be turned on.

When the period in which the light emitting transistor T_{EM} is turned on increases, the amount of current supplied to the light emitting device ED through the light emitting transistor T_{EM} can increase. The luminance of the light emitting device ED can vary based on the magnitude of the current flowing to the light emitting device ED.

Therefore, as the pulse width of the light emitting signal EM increases, the luminance of light output from the light emitting device ED can increase.

Further, when the pulse width of the light emitting signal EM supplied to the pixel circuit PC connected to the light emitting device outputting high-brightness light and the pulse width of the light emitting signal EM supplied to the pixel circuit PC connected to the light emitting device outputting low-brightness light are the same, the number of pulses of the light emitting signal EM supplied to the pixel circuit PC connected to the light emitting device outputting high-brightness light can be greater than the number of pulses of the light emitting signal EM supplied to the pixel circuit PC connected to the light emitting device outputting low-brightness light. For example, the frequency of the light emitting signal EM supplied to the pixel circuit PC connected to the light emitting device outputting high-brightness light can be greater than the frequency of the light emitting signal EM supplied to the pixel circuit PC connected to the light emitting device outputting low-brightness light.

When the frequency increases, the number of pulses increases. When the number of pulses supplied to the light emitting transistor T_{EM} increases, the number of times the light emitting transistor T_{EM} is turned on increases. When the number of times the light emitting transistor T_{EM} is turned on increases, the amount of current flowing to the light emitting device ED through the light emitting transistor T_{EM} can increase.

As described above, because the luminance of the light emitting device ED can be changed depending on the magnitude of the current flowing to the light emitting device ED, as the frequency of the light emitting signal EM increases or the number of pulses of the light emitting signal EM increases, the luminance of light output from the light emitting device ED can increase.

For example, the timing controller 300 or the sub-pixel driving part 410 can supply light emitting signals EM with different frequencies or different pulse widths to the light emitting transistor T_{EM} provided in the pixel circuit PC.

Accordingly, light having different luminance can be output from the light emitting devices ED connected to the pixel driving circuit PD.

Next, the cathode electrode driving part will be described as follows.

When the scan signal SC is supplied to the driving transistor T_{DR}, the cathode electrode driving part 420 can supply cathode voltages to the second electrodes CE2.

For example, as illustrated in FIG. 11A, when 16 pixels PX having a 4×4 shape are connected to the pixel driving circuit PD and one second electrode CE2 is connected to four pixels PX provided along the first direction X, 16 pixels PX can be provided in four rows 1H, 2H, 3H, and 4H, and the four rows 1H, 2H, 3H, and 4H can be spaced apart from each other along the second direction Y.

In this case, four pixels PX provided in each of the four rows 1H, 2H, 3H and 4H are connected to one second electrode CE2. Accordingly, four second electrodes CE2 are provided in the display panel 100 for driving the 16 pixels PX.

The four second electrodes CE2 are connected to one pixel driving circuit PD. The four second electrodes CE2 connected to one pixel driving circuit PD are referred to as sub-touch electrodes STE. For example, the sub-touch electrode STE include four second electrodes CE2.

To provide an additional description, at least one second electrode CE2 connected to the pixel driving circuit PD can be provided along the first direction X or row of the display panel 100, and at least two light emitting devices ED connected to the second electrode CE2 can be provided in a row along the first direction X or row.

In the above example, three sub-pixels SP are provided in each of the four pixels PX provided in the first row 1H.

Accordingly, when anode voltages are supplied from the 12 pixel circuits PC connected to the 12 sub-pixels SP provided in the first row 1H to the 12 anode electrodes 134 provided in the 12 sub-pixels SP, the cathode electrode driving part 420 can supply a cathode voltage to the second electrodes CE2 in the first row 1H. Accordingly, light can be output from the sub-pixels SP provided in the first row 1H.

This operation can be concurrently (or in some embodiments, simultaneously) performed in sub-pixels SP provided in the first row 1H and connected to other pixel driving circuits PD. Accordingly, light can be concurrently output from all sub-pixels SP provided in the first row 1H of the display panel 100.

Further, when anode voltages are supplied from the 12 pixel circuits PC connected to the 12 sub-pixels SP provided in the second row 2H to the 12 anode electrodes 134 provided in the 12 sub-pixels SP, the cathode electrode driving part 420 can supply a cathode voltage to the second electrodes CE2 provided in the second row 2H. Accordingly, light can be output from the sub-pixels SP provided in the second row 2H.

This operation can be concurrently performed in sub-pixels SP provided in the second row 2H and connected to other pixel driving circuits PD. Accordingly, light can be concurrently output from all sub-pixels SP provided in the second row 2H of the display panel 100.

By the above-described operations, light can be sequentially output from sub-pixels SP provided in all rows of the display panel 100, and thus, one image can be displayed through the display panel 100.

The sub-pixels SP can be individually driven by the structure and driving method as described above.

In order to perform the above operation, the cathode electrode driving part 420 can include control switches SW, as illustrated in FIG. 11A. Each of the control switches SW can connect the second electrode CE2 to the switch connection line CL.

In order to supply a cathode voltage to the second electrodes CE2 in the display period, and in order to supply a touch driving signal to the second electrodes CE2 in the touch sensing period, the control switches SW can be connected in various structures.

Each of the control switches SW can be turned on or off by a control signal received from the timing controller 300.

In the above example, one sub-touch electrode STE includes four second electrodes CE2, and the four second electrodes CE2 are connected to one pixel driving circuit PD.

In this case, the cathode electrode driving part 420 can include four control switches SW. Each of the four control switches SW is connected to the second electrode CE2 and the switch connection line CL.

During the display period in which an image is displayed on the display panel 100, the control switch SW can connect the second electrode CE2 to the switch connection line CL.

For example, each of the pixel driving circuits PD can supply a cathode voltage to at least one second electrode CE2 provided along the first direction X or row of the display panel 100 during the display period.

In the above example, one second electrode CE2 is provided in one row. Accordingly, the control switch SW can connect one second electrode CE2 provided in one row to the switch connection line CL during the display period. In this case, the cathode voltage switch 431 is turned on, and thus the switch connection line CL can be connected to the cathode voltage supply part 500. Accordingly, the second electrode CE2 can be connected to the cathode voltage supply part 500 through the control switch SW.

However, when two or more second electrodes CE2 are provided in one row, the control switch SW can connect two or more second electrodes CE2 provided in one row to the cathode voltage supply part 500.

As described above, when an anode voltage is supplied from the sub-pixel driving part 410 to the anode electrode 134 of the light emitting device ED through the first electrode CE1, and a cathode voltage is supplied from the cathode electrode driving part 420 to the cathode electrode 135 of the light emitting device ED through the second electrode CE2, light can be output from the light emitting device ED.

When the cathode voltage is sequentially supplied to the four second electrodes CE2 provided in the four rows 1H, 2H, 3H, and 4H, light can be sequentially output from the four rows 1H, 2H, 3H, and 4H.

The same operation can be performed in the sub-pixels SP connected to other pixel driving circuits PD.

Accordingly, light can be sequentially output from the rows of the display panel 100, and thus, one image can be displayed throughout the display panel 100.

Further, during the touch sensing period in which a touch is detected in the display panel 100, the control switch SW can connect the second electrode CE2 to the image signal line IL through the mode switch 433. In this case, the mode switch 433 can be turned on by the timing controller 300.

The display period for displaying an image and the touch sensing period for sensing a touch can be implemented in a time division method.

For example, each of the pixel driving circuits PD can supply a touch driving signal to all the second electrodes CE2 connected to the pixel driving circuit PD during the touch sensing period.

In the above example, one second electrode CE2 is provided in one row, and four second electrodes CE2 are provided in four rows. Accordingly, the control switches SW connect all four second electrodes CE2 to the image signal line IL during the touch sensing period. In this case, the touch driving signal output from the display driver 200 can be transmitted to the second electrode CE2 through the image signal line IL, the mode switch 433, and the control switch SW. Further, the touch sensing signal generated from the second electrode CE2 can be transmitted to the display driver 200 through the control switch SW, the mode switch 433, and the image signal line IL.

When two or more second electrodes CE2 are provided in one row, the control switch SW can connect the two or more second electrodes CE2 in one row to the image signal line IL.

When the touch driving signal is concurrently supplied to the four second electrodes CE2 provided in the four rows 1H, 2H, 3H, and 4H, a touch sensing signal can be generated in the four rows.

The touch sensing signal generated in the four rows can be transmitted to the display driver 200 through the mode switch 433 and the image signal line IL. The same operation can be performed in other pixel driving circuits PD.

In addition, each of the pixel driving circuits PD can supply a touch driving signal to at least one second electrode CE2 during the touch sensing period, and transmit a touch sensing signal received from at least one second electrode to the display driver 200.

The display driver 200 can determine whether there is a touch on the touch electrode TE by using the touch sensing signal transmitted from the at least one pixel driving circuit PD.

A method by which the display driver 200 determines whether the touch electrode TE is touched using a touch sensing signal transmitted from at least one pixel driving circuit PD has been described with reference to FIGS. 10A and 10B, so a detailed description thereof is omitted.

Next, the switching part 430 can include a cathode voltage switch 431, which is connected between the cathode voltage supply part 500 supplying the cathode voltage and the cathode electrode driving part 420, an image signal switch 432, which connects the image signal line IL to the sub-pixel driving part 410 or separates the image signal line IL from the sub-pixel driving part 410, and a mode switch 433, which is connected between the switch connection line CL connecting the cathode voltage switch 431 to the cathode electrode driving part 420 and the image signal line IL.

Because the structure and function of the switching part 430 have been described with reference to FIGS. 10A and 10B, a detailed description thereof is omitted.

Finally, as described above, in the display apparatus according to an embodiment of the present disclosure, pixels PX arranged in a 4×4 form as illustrated in FIG. 11A can be connected to the pixel driving circuit PD, pixels PX arranged in a 16×16 form as illustrated in FIG. 11B can be connected to the pixel driving circuit PD, or pixels PX arranged in various forms can be connected to the pixel driving circuit PD. Hereinafter, a structure of a display panel 100 applied to a display apparatus according to an embodiment of the present disclosure will be described with reference to FIGS. 11B and 11C. In the following descriptions, details that are the same as or similar to details described with reference to FIGS. 1 to 11A will be omitted or briefly described.

In a display apparatus according to another embodiment of the present disclosure, a pixel driving circuit PD and pixels PX1 to PX16 including light emitting devices ED electrically connected to the pixel driving circuit PD can be provided.

For example, as illustrated in FIG. 11B, the first to sixteenth pixels PX1 to PX16 can be arranged along the first direction X. A pixel PX can include a red sub-pixel, a green sub-pixel, and a blue sub-pixel SP.

A light emitting device ED can be disposed in the sub-pixel SP. At least one light emitting device ED can be disposed in one sub-pixel SP. For example, two light emitting devices can be disposed in one sub-pixel. One of the two light emitting devices can be a main light emitting device, and the other can be a redundancy light emitting device. The light emitting device ED can be a micro LED.

A red sub-pixel, a green sub-pixel, and a blue sub-pixel can be repeatedly disposed along the first direction X.

Sub-pixels SP that output light of the same color can be disposed along the second direction Y. For example, along the second direction Y, sub-pixels SP that output light of any one color of red, green, and blue can be disposed. The sub-pixels SP emitting light of the same color can be electrically connected through one first electrode line AND, as illustrated in FIG. 11C. The first electrode line AND can be connected to the first electrodes CE1.

The first electrode line AND can include a first line AND_P and a second line AND_R. The first line AND_P and the second line AND_R can be disposed to be spaced apart from each other in the first direction X. The first line AND_P can be connected to the main light emitting device, and the second line AND_R can be connected to the redundancy light emitting device.

Each of the second electrodes CE2 can extend in the first direction X, as illustrated in FIG. 11B. Further, each of the second electrodes CE2 can be arranged to be spaced apart from each other along the second direction Y. Accordingly, each of the second electrodes CE2 can be connected to the first to sixteenth pixels PX1 to PX16 disposed in each of the rows 1H to 16H.

The pixel driving circuit PD can be connected to the pixels PX1 to PX16 through the first electrodes CE1 and the second electrodes CE2. Accordingly, the pixel driving circuit PD can drive the light emitting devices ED arranged in the first to sixteenth rows 1H to 16H.

To provide an additional description, the pixel driving circuit PD can be electrically connected to the light emitting devices arranged in the first to 16th rows 1H to 16H through the first electrodes CE1 and the second electrodes CE2, and the pixel driving circuit PD can supply the control signal and power to the light emitting devices ED through the first electrodes CE1 and the second electrodes CE2 to control the light emitting operation of the light emitting devices ED.

In this case, the second electrodes CE2 can be connected to the pixels PX and the pixel driving circuit PD in the form illustrated in FIG. 11B, the first electrodes CE1 provided in the pixels PX can be connected to the first electrode lines AND in the form illustrated in FIG. 11C, and the first electrodes CE1 can be connected to the pixel driving circuit PD through the first electrode lines AND.

For example, in the light emitting device part EDU, as illustrated in FIG. 11C, first electrode lines AND can be disposed on the upper and lower sides of the pixel driving circuit PD, respectively.

As illustrated in FIG. 11C, one first electrode line AND among the first electrode lines AND can connect the first electrodes CE1 of the light emitting devices ED adjacent to each other in the vertical direction among the light emitting devices ED.

In this case, a pixel circuit PC can be connected to each of the first electrode lines AND. However, the pixel circuit PC can be connected to at least two first electrode lines AND. In this case, the anode voltage can be sequentially supplied to at least two first electrode lines AND.

Hereinafter, the basic driving method of the display apparatus according to an embodiment of the present disclosure in the display period in which the image is displayed will be briefly described.

FIG. 11D is an example diagram illustrating a light emitting signal applied to a display apparatus according to an embodiment of the present disclosure, and FIG. 11E is an example diagram illustrating a pixel circuit applied to a display apparatus according to an embodiment of the present disclosure.

As described above, the pixel driving circuit PD can control the light emitting operation of the light emitting device ED by using the pulse width of the light emitting signal EM.

For example, as illustrated in FIG. 11D, the pixel driving circuit PD can adjust the pulse width of the light emitting signal EM, and thus, light corresponding to 1 Gray to 32 Gray can be output through the light emitting device ED.

The pixel driving circuit PD can supply a light emitting signal EM having a pulse width adjusted based on gray to a gate electrode of the light emitting transistor T_{EM}.

In this case, a fixed light emitting current can be applied to the light emitting device ED through the light emitting transistor T_{EM}, and thus, the light emitting device ED can output light.

For example, when eight light emitting devices ED are connected to one first electrode line AND, the eight light emitting devices ED can output light by constant current having the same current value.

In this case, in a typical organic light emitting display apparatus, the amount of current flowing to the light emitting device is different because the voltage applied to the gate electrode of the driving transistor varies from one light emitting device to another, and the time for which the current flows to the light emitting devices is the same.

However, in the display apparatus according to an embodiment of the present disclosure, the amount of current flowing to the light emitting devices ED is the same, and the time for which the current flows is different for each light emitting device. For example, the time for which the current flows through the light emitting device can be adjusted by the pulse width of the light emitting signal (PWM signal) EM.

For example, the pixel circuit PC, as illustrated in FIGS. 4 and 11E, includes a driving transistor T_{DR} and a light emitting transistor T_{EM}, and is connected to light emitting devices. Reference numerals 1H, 2H, and 8H illustrated in FIG. 11E refer to light emitting devices ED provided in the first row 1H, the second row 2H, and the eighth row 8H illustrated in FIG. 11B.

A high potential voltage AVDD can be applied to the first electrode of the driving transistor T_{DR}, a light emitting transistor T_{EM} can be connected to the second electrode of the driving transistor T_{DR}, and a reference voltage VREF or initialization voltage VINIT can be applied to the gate electrode of the driving transistor T_{DR}. The reference voltage VREF or the initialization voltage VINIT can be a scan signal SC.

For example, a reference voltage VREF can be applied to the gate electrode of the driving transistor T_{DR} through a switching means (e.g., one or more switches, one or more switching units, etc.), or an initialization voltage VINIT can be applied to the gate electrode of the driving transistor T_{DR} through a voltage buffer (VB) and a switching means (e.g., one or more switches, one or more switching units, etc.).

A driving transistor T_{DR} can be connected to the first electrode of the light emitting transistor T_{EM}, light emitting devices can be connected to the second electrode of the light emitting transistor T_{EM}, and a light emitting signal EM can be applied to the gate electrode of the light emitting transistor T_{EM}.

Hereinafter, a display period in which an image is displayed and a touch sensing period in which a touch is detected will be briefly described with reference to FIGS. 11F and 11G.

FIG. 11F is an example diagram illustrating a touch sensing method in a display apparatus according to an embodiment of the present disclosure, and FIG. 11G is an example diagram illustrating a display period and a touch sensing period applied to a display apparatus according to an embodiment of the present disclosure.

In the display apparatus according to an embodiment of the present disclosure, the second electrodes CE2 can be used as a touch electrode TE, and this structure is referred to as an in-cell touch structure. Because a separate touch electrode is not provided in the display apparatus according to an embodiment of the present disclosure, the thickness of the display panel can be reduced.

For example, when the cover member 120 is touched by the user, the first capacitance C1 between the second electrodes CE2 and the cover member 120 which are provided on the display panel 100 and the second capacitance C2 between the second electrodes CE2 and the signal lines can be changed, as illustrated in FIG. 11F.

The touch sensing signal generated by the change of the first capacitance C1 and the second capacitance C2 can be transmitted to the pixel driving circuit PD through the second electrodes CE2. In this case, the pixel driving circuit PD can be connected to the ground part GND.

The touch sensing signals transmitted to the pixel driving circuit PD can be transmitted to the display driver 200, and the display driver 200 can determine whether there is a touch on the touch electrode TE by using the touch sensing signals transmitted from the at least one pixel driving circuit PD.

One frame period (1 Frame Period) can mean, as an example, a period in which one image is displayed through the display panel 100. As illustrated in FIG. 11G, one frame period can include a display period DP and a touch sensing period TP. In one frame period, the touch sensing period TP and the display period DP can be different. For example, the touch sensing period TP can be shorter than the display period DP.

The touch sensing period TP can be a contact touch sensing period CTP or a hover touch sensing period HTP.

For example, as illustrated in FIG. 11G, in a first occurring one frame period 1st FP, the contact touch sensing period CTP can occur after the display period DP. Further, in a second occurring one frame period 2nd FP, the hover touch sensing period HTP can occur after the display period DP.

The cycle in which the display period DP and the touch sensing period TP are repeated in one frame period and the cycle in which the contact touch sensing period CTP and the hover touch sensing period HTP are repeated can be variously changed.

Touch PWM illustrated in FIG. 11G means, as an example, a touch driving signal generated by the display driver 200 during the touch sensing period. In this case, the magnitude of the touch driving signal generated during the contact touch sensing period CTP can be the same as the magnitude of the touch driving signal generated during the hover touch sensing period HTP, but can be different as illustrated in FIG. 11G.

Further, Hover Enable illustrated in FIG. 11G can be a control signal supplied from the timing controller 300 to the display driver 200. For example, the display driver 200 can recognize the hover touch sensing period HTP by the Hover Enable, and various switches provided in the display driver 200 can be turned on or off depending on the Hover Enable.

Moreover, Vsync illustrated in FIG. 11G can be a control signal supplied from the timing controller 300 to the display driver 200, and the Vsync can be a control signal that distinguishes between the display period DP and the touch sensing period TP.

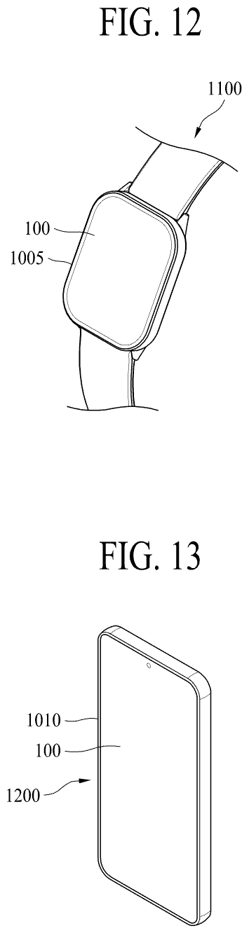

FIGS. 12 to 15 are diagrams illustrating electronic devices to which a display apparatus according to embodiments of the present disclosure is applied.

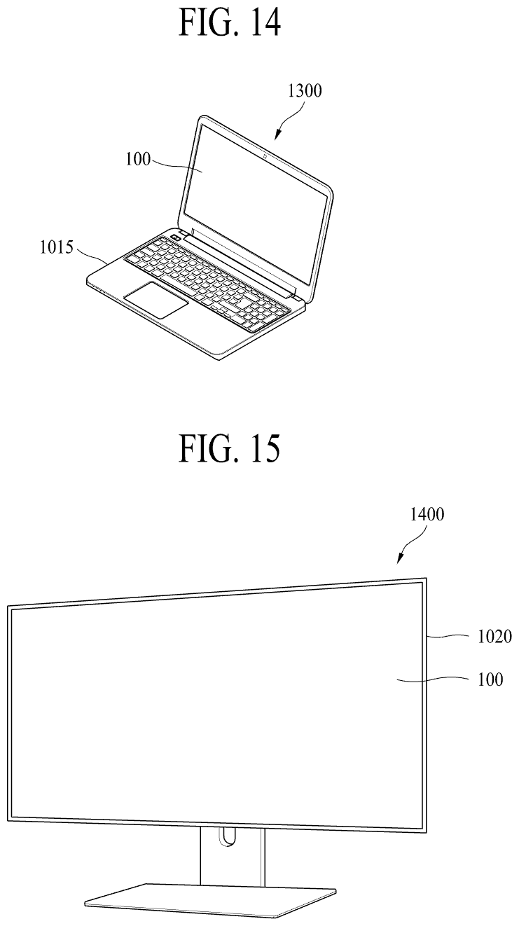

Referring to FIGS. 12 to 15, the display apparatus according to embodiments of the present disclosure can be included in various electronic devices. For example, various electronic devices can be a wearable device 1100 as illustrated in FIG. 12, a mobile device 1200 as illustrated in FIG. 13, a laptop 1300 as illustrated in FIG. 14, or a monitor or TV 1400 as illustrated in FIG. 15, but embodiments of the present disclosure are not limited thereto.

Each of the wearable device 1100, the mobile device 1200, the laptop 1300, and the monitor or TV 1400 can include a case part 1005, 1010, 1015, and 1020, and a display panel 100 and a display apparatus 1000 according to embodiments of the present disclosure described above. For instance, the display panel 100 and/or the display apparatus 1000 according to one or more embodiments of the present disclosure can be used and included in electronic devices such as wearable devices, mobile devices such as smart phones, laptops, navigation devices, monitors, TVs, different types of display devices, vehicles, cameras, home appliances, gaming devices, etc.

For example, the display apparatus according to an embodiment of the present disclosure can be applied to a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), PDA (personal digital assistant), an MP3 player, a mobile medical device, a desktop PC, a laptop PC, a netbook computer, a workstation, a navigation, a vehicle display, a theater display, a television, a wall paper device, a signage device, a game device, a laptop, a game device, a monitor, a camera, a camcorder or a home appliance.

The features of the display apparatus according to embodiments of the present disclosure are briefly summarized as follows.

A display apparatus according to an embodiment of the present disclosure comprises a substrate including a display area and a non-display area, pixel driving circuits disposed in the display area, first electrodes connected to the pixel driving circuits, light emitting devices disposed on the first electrodes, and second electrodes disposed on the light emitting devices, wherein an image signal line is connected to a pixel driving circuit, and wherein the pixel driving circuit is configured to selectively connect the image signal line to the first electrodes or the second electrodes.

At least two second electrodes connected to the pixel driving circuit are used as one touch electrode.

Each of the at least two second electrodes extend along a first direction of the substrate, and the at least two second electrodes are provided along a second direction different from the first direction.

When a cathode voltage is supplied to any one of the at least two second electrodes, light is emitted from light emitting devices connected to the second electrode to which the cathode voltage is supplied.

When the at least two second electrodes are used as one touch electrode, a touch driving signal is simultaneously supplied to the at least two second electrodes.

During a display period in which an image is displayed, image signals used to drive the light emitting devices are supplied to the pixel driving circuit through the image signal line, and during a touch sensing period in which a touch is detected, touch sensing signals transmitted from the second electrodes are output to the image signal line.

The pixel driving circuit comprises a cathode electrode driving part that supplies a cathode voltage or a touch driving signal to the second electrodes; a sub-pixel driving part that supplies anode voltages to the first electrodes; and a switching part that connects the image signal line to the cathode electrode driving part or the sub-pixel driving part.

The switching part comprises a cathode voltage switch connected between a cathode voltage supply part supplying the cathode voltage and the cathode electrode driving part; an image signal switch that connects the image signal line to the sub-pixel driving part or separates the image signal line from the sub-pixel driving part; and a mode switch that is connected between a switch connection line connecting the cathode voltage switch to the cathode electrode driving part and the image signal line.

A display apparatus according to an embodiment of the present disclosure further comprises a cathode voltage supply part that generates a cathode voltage to be supplied to the second electrodes and supplies the cathode voltage to the pixel driving circuit.

A display apparatus according to an embodiment of the present disclosure further comprises a display driver that supplies image signals to the image signal line, or detects a touch on the substrate using touch sensing signals transmitted from the second electrodes through the image signal line.

Second electrodes driven by at least one pixel driving circuit form a touch electrode, a touch sensing period in which a touch is detected includes a contact touch sensing period during which a touch by an object contacting the display area is detected, and a hover touch sensing period during which a touch by an object spaced apart from the display area is detected, in the contact touch sensing period, the display driver detects a touch on the touch electrode corresponding to a touch coordinate by using touch sensing signals received from at least one pixel driving circuit, and in the hover touch sensing period, the display driver detects a touch on the touch electrode corresponding to a touch coordinate by using touch sensing signals received from a greater number of pixel driving circuits than the number of pixel driving circuits that transmit touch sensing signals during the contact touch sensing period.

Second electrodes driven by at least one pixel driving circuit form a touch electrode, a touch sensing period in which a touch is detected includes a contact touch sensing period during which a touch by an object contacting the display area is detected, and a hover touch sensing period during which a touch by an object spaced apart from the display area is detected, and the size of a touch electrode TE recognized as a touch coordinate during the hover touch sensing period is larger than the size of a touch electrode recognized as a touch coordinate during the contact touch sensing period.

The display driver comprises an image signal generation part that generates the image signals; a touch determination part that generates touch driving signals and detects a touch on the substrate by using touch sensing signals received from the image signal lines; a signal switching part that connects the image signal lines to the image signal generation part or the touch determination part; and a group switching part that is provided between the signal switching part and the touch determination part.

The signal switching part includes signal switches connected to the image signal lines, and at least two of the signal switches are connected to the group switching part through a group line.

At least two image signal lines connected to the at least two signal switches are connected to at least two pixel driving circuits, and second electrodes driven by the at least two pixel driving circuits form one touch electrode.

The group switching part comprises at least two group switches connected to at least two group lines connected to the signal switching part; and connection switches provided between the at least two group lines, and wherein each of the connection switches is provided between two adjacent group lines.

The touch determination part comprises at least two determination parts connected to the at least two group switches.

A touch sensing period in which a touch is detected includes a contact touch sensing period during which a touch by an object contacting the display area is detected, and a hover touch sensing period during which a touch by an object spaced apart from the display area is detected, and during the contact touch sensing period, the at least two determination parts are driven to detect a touch on the substrate.

During the hover touch sensing period, at least one of the at least two determination parts is driven to detect a touch on the substrate.

Each of the at least two determination parts generates a touch driving signal and transmits it to the group switching part, and detects a touch on the substrate by using a touch sensing signal received through the group switching part.

According to an embodiment of the present disclosure, the size of the touch electrode in the hover touch sensing period in which a touch by an object spaced apart from the display panel is detected can be larger than the size of the touch electrode in the contact touch sensing period in which a touch by an object in contact with the display panel is detected.

Accordingly, the size of the touch sensing signal corresponding to one coordinate received during the hover touch sensing period can be larger than the size of the touch sensing signal corresponding to one coordinate received during the contact touch sensing period.

As the size of the touch sensing signal increases during the hover touch sensing period, sensitivity to sense a hover touch can be improved. Accordingly, whether a hover touch has occurred can be accurately determined.

Moreover, according to an embodiment of the present disclosure, sensitivity to sense a hover touch can be improved even if the size of a touch driving signal for sensing a hover touch is not increased during the hover touch sensing period. Accordingly, a display apparatus having low power characteristics can be provided, and accordingly, a display apparatus capable of implementing an Environment/Social/Governance (ESG) can be provided.

The above-described features, structures, and effects of the present disclosure are included in at least one embodiment of the present disclosure, but are not limited to only one embodiment. Furthermore, the features, structures, and effects described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

What is claimed is:

1. A display apparatus comprising:
a substrate including a display area and a non-display area;
pixel driving circuits disposed in the display area;
first electrodes connected to the pixel driving circuits;
light emitting devices disposed on the first electrodes; and
second electrodes disposed on the light emitting devices,
wherein an image signal line is connected to a pixel driving circuit among the pixel driving circuits, and
wherein the pixel driving circuit is configured to selectively connect the image signal line to the first electrodes or the second electrodes.

2. The display apparatus of claim 1, wherein at least two second electrodes among the second electrodes are connected to the pixel driving circuit and are used as one touch electrode.

3. The display apparatus of claim 2, wherein
each of the at least two second electrodes extends along a first direction of the substrate, and
the at least two second electrodes are spaced apart from each other along a second direction different from the first direction.

4. The display apparatus of claim 3, wherein when a cathode voltage is supplied to one of the at least two second electrodes, light is emitted from light emitting devices connected to the one of the at least two second electrodes to which the cathode voltage is supplied.

5. The display apparatus of claim 3, wherein when the at least two second electrodes are used as one touch electrode, a touch driving signal is simultaneously supplied to the at least two second electrodes.

6. The display apparatus of claim 1, wherein
during a display period in which an image is displayed, image signals used to drive the light emitting devices are supplied to the pixel driving circuit through the image signal line, and
during a touch sensing period in which a touch is detected, touch sensing signals transmitted from the second electrodes are output to the image signal line.

7. The display apparatus of claim 1, wherein the pixel driving circuit comprises:
a cathode electrode driving part that supplies a cathode voltage or a touch driving signal to the second electrodes;
a sub-pixel driving part that supplies anode voltages to the first electrodes; and
a switching part that connects the image signal line to the cathode electrode driving part or the sub-pixel driving part.

8. The display apparatus of claim 7, wherein the switching part comprises:
a cathode voltage switch connected between a cathode voltage supply part configured to supply the cathode voltage and the cathode electrode driving part;
an image signal switch that connects the image signal line to the sub-pixel driving part or separates the image signal line from the sub-pixel driving part; and
a mode switch connected between the image signal line and a switch connection line configured to connect the cathode voltage switch to the cathode electrode driving part.

9. The display apparatus of claim 1, further comprising a cathode voltage supply part that generates a cathode voltage to be supplied to the second electrodes and supplies the cathode voltage to the pixel driving circuit.

10. The display apparatus of claim 1, further comprising a display driver that supplies image signals to the image signal line, or detects a touch on the substrate using touch sensing signals transmitted from the second electrodes through the image signal line.

11. The display apparatus of claim 10, wherein
second electrodes driven by at least one pixel driving circuit form a touch electrode,
a touch sensing period in which a touch is detected includes:
a contact touch sensing period during which a touch by an object contacting the display area is detected, and
a hover touch sensing period during which a touch by an object spaced apart from the display area is detected,
in the contact touch sensing period, the display driver detects a touch on the touch electrode corresponding to a touch coordinate by using touch sensing signals received from the at least one pixel driving circuit, and
in the hover touch sensing period, the display driver detects a touch on the touch electrode corresponding to a touch coordinate by using touch sensing signals received from a greater number of pixel driving circuits than the number of pixel driving circuits that transmit touch sensing signals during the contact touch sensing period.

12. The display apparatus of claim 10, wherein
second electrodes driven by at least one pixel driving circuit form a touch electrode,
a touch sensing period in which a touch is detected includes:
a contact touch sensing period during which a touch by an object contacting the display area is detected, and
a hover touch sensing period during which a touch by an object spaced apart from the display area is detected, and
a size of a touch electrode recognized as a touch coordinate during the hover touch sensing period is larger than a size of a touch electrode recognized as a touch coordinate during the contact touch sensing period.

13. The display apparatus of claim 10, wherein the display driver comprises:
an image signal generation part that generates the image signals;
a touch determination part that generates touch driving signals and detects a touch on the substrate by using touch sensing signals received from the image signal lines;
a signal switching part that connects the image signal lines to the image signal generation part or the touch determination part; and
a group switching part provided between the signal switching part and the touch determination part.

14. The display apparatus of claim 13, wherein
the signal switching part includes signal switches connected to the image signal lines, and
at least two of the signal switches are connected to the group switching part through a group line.

15. The display apparatus of claim 14, wherein
at least two image signal lines connected to the at least two of the signal switches are connected to at least two pixel driving circuits among the pixel driving circuits, and
second electrodes driven by the at least two pixel driving circuits form one touch electrode.

16. The display apparatus of claim 14, wherein the group switching part comprises:
at least two group switches connected to at least two group lines connected to the signal switching part; and
connection switches provided between the at least two group lines, and
wherein each of the connection switches is provided between two adjacent group lines.

17. The display apparatus of claim 16, wherein the touch determination part comprises at least two determination parts connected to the at least two group switches.

18. The display apparatus of claim 17, wherein
a touch sensing period in which a touch is detected includes:
a contact touch sensing period during which a touch by an object contacting the display area is detected, and
a hover touch sensing period during which a touch by an object spaced apart from the display area is detected, and
during the contact touch sensing period, the at least two determination parts are driven to detect a touch on the substrate.

19. The display apparatus of claim 18, wherein during the hover touch sensing period, at least one of the at least two determination parts is driven to detect a touch on the substrate.

20. The display apparatus of claim 17, wherein
each of the at least two determination parts generates a touch driving signal and transmits the touch driving signal to the group switching part, and detects a touch on the substrate by using a touch sensing signal received through the group switching part.
